(19) United States
(12) Patent Application Publication
(10) Pub. No.: US 2019/0022995 A1
(43) Pub. Date: Jan. 24, 2019

(54) PRINTING METHOD

(71) Applicants: FUJIFILM Corporation, Tokyo (JP); Japan Advanced Printed Electronics Technology Research Association, Ibaraki (JP)

(72) Inventors: Mitsuhisa ITOH, Tsukuba-shi (JP); Kenichi KODAMA, Kanagawa (JP)

(73) Assignees: FUJIFILM Corporation, Tokyo (JP); Japan Advanced Printed Electronics Technology Research Association, Ibaraki (JP)

(21) Appl. No.: 16/131,072

(22) Filed: Sep. 14, 2018

Related U.S. Application Data
(63) Continuation of application No. PCT/JP2017/012953, filed on Mar. 29, 2017.

(30) Foreign Application Priority Data
Mar. 30, 2016 (JP) 2016-068194

(51) Int. Cl. B41F 3/81; B41F 31/08; B41J 2/01; B41J 2/005; B41J 11/00; B41M 1/10; H05K 3/12

(52) U.S. Cl. CPC B41F 3/81; B41F 31/08; B41J 2/01; H05K 3/12; B41J 11/0015; B41M 1/10; B41J 2/0057

(57) ABSTRACT

Provided is a printing method which enables formation of a high-definition printing pattern with high productivity. The printing method includes a treatment liquid application step of applying a treatment liquid, in a treatment liquid set pattern, to a pattern formation region of a printing plate in the printing plate on which a pattern has been formed; an ink application step of applying an ink, in an ink set pattern, to the pattern formation region of the printing plate to which the treatment liquid has been applied; and a transfer step of transferring the ink applied to the pattern formation region of the printing plate to a substrate. The treatment liquid is used for increasing a second diameter of the ink after application of the treatment liquid compared to a first diameter of the ink landed on the pattern formation region without application of the treatment liquid.

### CROSS-REFERENCE TO RELATED APPLICATIONS

This application is a Continuation of PCT International Application No. PCT/JP2017/012953 filed on Mar. 29, 2017, which claims priority under 35 U.S.C. § 119(a) to Japanese Patent Application No. 2016-068194 filed on Mar. 30, 2016. The above application is hereby expressly incorporated by reference, in its entirety, into the present application.

### BACKGROUND OF THE INVENTION

### 1. Field of the Invention

The present invention relates to a printing method of applying a treatment liquid to a pattern formation region of a printing plate in a treatment liquid set pattern and particularly relates to a printing method of forming a high-definition printing pattern with high productivity.

### 2. Description of the Related Art

Currently, printing is used not only for forming characters and photos but also for forming a patterned wiring and a wiring board.

JP2013-241013A describes a printing method of patterning a gating agent on a plate having an entirely hydrophilic surface using an ink jet, coating the plate with an ink, and transferring the plate to a blanket and then to a substrate to form a pattern. Further, JP2013-241013A also describes a printing method of patterning a gating agent on a portion expected to change the pattern, on a plate having a fixed pattern, using an ink jet, coating an intermediate transfer member with an ink, and transferring the intermediate transfer member to a blanket and then to a substrate to form a pattern.

JP2010-241039A describes a method of producing a recorded material formed by using an intermediate transfer member that includes a base material obtained by performing a step of applying a liquid containing a surfactant to a surface of a liquid-repellent object such that the liquid adheres thereto in a liquid droplet shape; a step of lyophilizing the outer surface of the adhered liquid droplet by performing a plasma treatment thereon after the application; and a step of removing the liquid on the liquid-repellent surface after lyophilization. A pattern formed of a lyophilic portion and a liquid-repellent portion is formed on the intermediate transfer member.

In JP2010-241039A, a reaction solution that reacts with an ink is applied to the intermediate transfer member, and the reaction solution is held by the lyophilic portion. In this state, an ink image is formed on the intermediate transfer member by jetting an ink from an ink jet head to the intermediate transfer member. At this time, since the ink instantaneously undergoes an aggregation reaction due to the contact with the reaction solution, the ink image is not disturbed. Thereafter, the ink image formed on the intermediate transfer member is transferred to a recording medium.

JP2002-137528A describes a hybrid stencil printing device that prevents bleeding of an ink by performing pre-coating on a stencil printing unit using a stencil and performing inking using an ink jet printing unit.

### SUMMARY OF THE INVENTION

In JP2013-241013A, since the portion which has not been coated with the ink is covered with a gating agent using an ink jet, high-accuracy patterning cannot be performed. Therefore, a high-definition pattern cannot be obtained.

In JP2010-241039A, a pattern formed of a lyophilic portion and a liquid-repellent portion is formed by applying the liquid containing a surfactant to the intermediate transfer member and performing a plasma treatment. Accordingly, high-definition pattern cannot be obtained, and thus a high-definition ink image cannot be obtained.

In JP2002-137528A, high productivity is difficult to be realized because stencil needs to be prepared according to the pattern. In JP2002-137528A, bleeding of an ink is prevented by performing pre-coating and pattern formation is not carried out by bleeding an ink.

An object of the present invention is to solve the above-described problems of the related art and is to provide a printing method which enables formation of a high-definition printing pattern with high productivity.

In order to achieve the above-described object, according to a first aspect of the present invention, there is provided a printing method comprising: a treatment liquid application step of applying a treatment liquid, in a treatment liquid set pattern, to a pattern formation region of a printing plate in the printing plate on which a pattern has been formed; an ink application step of applying an ink, in an ink set pattern, to the pattern formation region of the printing plate to which the treatment liquid has been applied; and a transfer step of transferring the ink applied to the pattern formation region of the printing plate to a substrate, in which the treatment liquid is used for increasing a second diameter of the ink after application of the treatment liquid compared to a first diameter of the ink landed on the pattern formation region without application of the treatment liquid.

It is preferable that the ink application step is repeatedly performed a plurality of times after the treatment liquid application step has been repeatedly performed a plurality of times, and then the transfer step is performed.

It is preferable that the transfer step is performed after the treatment liquid application step and the ink application step have been repeatedly performed a plurality of times.

According to a second aspect of the present invention, there is provided a printing method comprising: an ink application step of applying an ink, in an ink set pattern, to a pattern formation region of a printing plate in the printing plate on which a pattern has been formed; a treatment liquid application step of applying a treatment liquid, in a treatment liquid set pattern, to the pattern formation region of the printing plate to which the ink has been applied; and a transfer step of transferring the ink applied to the pattern formation region of the printing plate to a substrate, in which the treatment liquid is used for increasing a second diameter of the ink after application of the treatment liquid compared to a first diameter of the ink landed on the pattern formation region without application of the treatment liquid.

It is preferable that the treatment liquid application step is repeatedly performed a plurality of times after the ink application step has been repeatedly performed a plurality of times, and then the transfer step is performed.

It is preferable that the transfer step is performed after the ink application step and the treatment liquid application step have been repeatedly performed a plurality of times.

It is preferable that the treatment liquid is applied according to an ink jet method. It is preferable that the ink is applied according to an ink jet method. It is preferable that at least a part of the treatment liquid set pattern overlaps with at least a part of the ink set pattern.

It is preferable that the printing method is used for producing an electronic device or for forming a wiring pattern or an electrode.

According to the present invention, it is possible to form a high-definition printing pattern with high productivity.

### BRIEF DESCRIPTION OF THE DRAWINGS

FIG. 1 is a schematic view illustrating a printing device according to an embodiment of the present invention.

FIG. 2 is a schematic view illustrating an image recording unit of the printing device according to the embodiment of the present invention.

FIG. 3 is a schematic view illustrating an example of a printing plate.

FIG. 4 is a plan view illustrating arrangement of nozzles in an ink jet head.

FIG. 5 is a plan view illustrating another example of arrangement of the nozzles in the ink jet head.

FIG. 6 is a schematic view illustrating an example of a printing plate used for the printing device according to the embodiment of the present invention.

FIG. 7 is a schematic cross-sectional view illustrating the example of the printing plate used for the printing device according to the embodiment of the present invention.

FIG. 8 is a schematic cross-sectional view illustrating a planographic plate which is a printing plate used for the printing device according to the embodiment of the present invention.

FIG. 9 is a schematic cross-sectional view illustrating a relief printing plate which is a printing plate used for the printing device according to the embodiment of the present invention.

FIG. 10 is a schematic view illustrating an example of a thin film transistor formed by the printing device according to the embodiment of the present invention.

FIG. 11 is a graph showing the relationship between an ink diameter ratio and a time taken from jetting of a treatment liquid to jetting of an ink.

FIG. 12 is a schematic view for describing an interaction between the ink and the treatment liquid.

FIG. 13 is a schematic view for describing the interaction between the ink and the treatment liquid.

FIG. 14 is a schematic view illustrating a treatment liquid set pattern.

FIG. 15 is a schematic view illustrating an ink set pattern of an ink.

FIG. 16 is a schematic view illustrating the treatment liquid set pattern and the ink set pattern of the ink.

FIG. 17 is a schematic view illustrating another ink set pattern of the ink.

FIG. 18 is a schematic view illustrating the treatment liquid set pattern and the other ink set pattern of the ink.

FIG. 19 is a schematic view illustrating a first printing method according to the embodiment of the present invention in order of steps.

FIG. 20 is a schematic view illustrating the first printing method according to the embodiment of the present invention in order of steps.

FIG. 21 is a schematic view illustrating the first printing method according to the embodiment of the present invention in order of steps.

FIG. 22 is a schematic view illustrating the first printing method according to the embodiment of the present invention in order of steps.

FIG. 23 is a schematic view illustrating the first printing method according to the embodiment of the present invention in order of steps.

FIG. 24 is a schematic cross-sectional view illustrating the first printing method according to the embodiment of the present invention in order of steps.

FIG. 25 is a schematic cross-sectional view illustrating the first printing method according to the embodiment of the present invention in order of steps.

FIG. 26 is a schematic cross-sectional view illustrating the first printing method according to the embodiment of the present invention in order of steps.

FIG. 27 is a schematic cross-sectional view illustrating the first printing method according to the embodiment of the present invention in order of steps.

FIG. 28 is a schematic cross-sectional view illustrating the first printing method according to the embodiment of the present invention in order of steps.

FIG. 29 is a schematic cross-sectional view illustrating the first printing method according to the embodiment of the present invention in order of steps.

FIG. 30 is a schematic view illustrating a second printing method according to the embodiment of the present invention in order of steps.

FIG. 31 is a schematic view illustrating the second printing method according to the embodiment of the present invention in order of steps.

FIG. 32 is a schematic view illustrating the second printing method according to the embodiment of the present invention in order of steps.

FIG. 33 is a schematic view illustrating a third printing method according to the embodiment of the present invention in order of steps.

FIG. 34 is a schematic view illustrating the third printing method according to the embodiment of the present invention in order of steps.

FIG. 35 is a timing chart showing the timing for application of the treatment liquid and the ink according to the printing method of the embodiment of the present invention.

FIG. 36 is a flowchart showing the printing method according to the embodiment of the present invention.

FIG. 37 is a flowchart showing another printing method according to the embodiment of the present invention.

### DESCRIPTION OF THE PREFERRED EMBODIMENTS

Hereinafter, a printing method of the present invention will be described in detail based on preferred embodiments illustrated in the accompanying drawings. The present invention is not limited to the embodiments of the printing device and the printing method described below.

Further, the numerical ranges shown using “to” indicate ranges including the numerical values described before and after “to”. For example, the expression “ε is in a range of a numerical value β1 to a numerical value β2” means that the range of c includes the numerical value β1 and the numerical value β2 and is represented by “β1≤ε≤β2” using a mathematical symbol.

Further, for example, an angle of “parallel”, “vertical”, or “orthogonal” means that a difference between this angle and the exact angle is less than 5 degrees unless otherwise specified. The difference between this angle and the exact angle is preferably less than 4 degrees and more preferably less than 3 degrees. Further, the “same” includes a usually acceptable error range in the technical field.

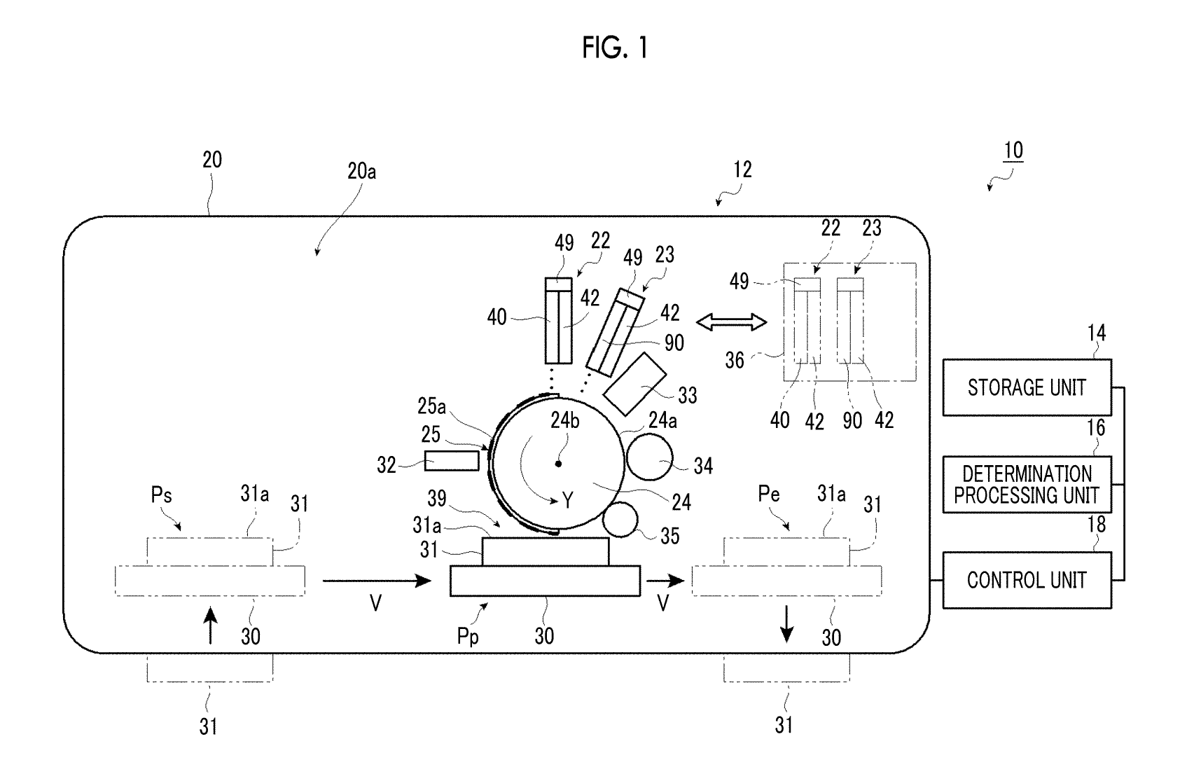

FIG. 1 is a schematic view illustrating a printing device according to an embodiment of the present invention.

A printing device 10 illustrated in FIG. 1 includes a printing device main body 12, a storage unit 14, a determination processing unit 16, and a control unit 18.

The printing device main body 12 forms a predetermined pattern on a substrate 31 according to a printing method. The printing device main body 12 will be described below in detail.

The storage unit 14 stores various pieces of information to be used by the printing device 10. The storage unit 14 stores information related to a reference shape serves as a reference of a plate surface 25a of a printing plate 25 in which an ink has been applied to a specific pattern.

The reference shape information is image data showing an ideal state at the time of application of the ink to a pattern formation region of the printing plate 25. Further, in a case where the ink is applied to the pattern formation region of the printing plate 25 a plurality of times, the reference shape information is image data showing an ideal state for each time. For example, in a case where the ink is jetted to the pattern formation region according to an ink jet method to form dots and the ink is applied to the pattern formation region, the reference shape information is image data showing ideal arrangement of dots to be formed by the ink being jetted for each time.

Further, the reference shape information also includes image data showing an ideal state of the plate surface 25a of the printing plate 25 after transfer.

Further, the storage unit 14 stores ink set pattern data of a pattern intended to be printed and treatment liquid set pattern data of a treatment liquid. The ink set pattern data and the treatment liquid set pattern data are appropriately input from the outside and stored in the storage unit 14. A method of inputting the reference shape information, the ink set pattern data, and the treatment liquid set pattern data to the storage unit 14 is not particularly limited. For example, various interfaces are provided in the storage unit 14, and the information and the data can be input to the storage unit 14 via a storage medium and a wired or wireless network.

Further, the storage unit 14 will be described below, corrected ink set pattern data obtained by correcting ink set pattern data and ink jetting timing data of an ink to be jetted from the ink jet head 40, and ink set pattern data of the ink according to the attachment state of the printing plate 25 is also stored in the storage unit 14.

The ink set pattern data of the ink indicates data showing the ink set pattern of the ink at the time of application of the ink to a pattern formation region 27a (see FIG. 3) of the printing plate 25 using the ink jet head 40, in this case, a jetting pattern of the ink. The ink set pattern will be described below.

The ink jetting timing data indicates data showing the timing at which the ink is jetted to the pattern formation region of the printing plate 25 at the time of application of the ink to the pattern formation region of the printing plate 25 based on the above-described ink set pattern data using the ink jet head 40.

The storage unit 14 will be described in detail after the description of the processing unit 23, and corrected treatment liquid set pattern data obtained by correcting the treatment liquid set pattern data and the treatment liquid jetting timing data of a set pattern for the treatment liquid which has been preset in order to apply the treatment liquid and the treatment liquid set pattern data according to the attachment state of the printing plate 25 is also stored in the storage unit 14.

The treatment liquid set pattern data indicates data showing a set pattern of the treatment liquid at the time of application of the treatment liquid to the pattern formation region of the printing plate 25. The treatment liquid set pattern will be described below.

The treatment liquid jetting timing data indicates data showing the timing at which the treatment liquid is jetted to the pattern formation region of the printing plate 25 at the time of application of the treatment liquid to the pattern formation region of the printing plate 25 based on the above-described treatment liquid set pattern data.

The determination processing unit 16 also creates corrected treatment liquid set pattern data with respect to the treatment liquid set pattern data similar to the ink set pattern data according to an angle α of the printing plate 25. The corrected treatment liquid set pattern data is stored in the storage unit 14.

The control unit 18 is connected to the printing device main body 12, the storage unit 14, and the determination processing unit 16 and controls each element of the printing device main body 12, the storage unit 14, and the determination processing unit 16. Further, the control unit 18 controls each unit according to the determination results from the determination processing unit 16.

Further, for example, in a case where corrected ink set pattern data of the ink set pattern data is created by the determination processing unit 16, the control unit 18 allows the ink jet head 40 to jet the ink based on the corrected ink set pattern data.

Next, the printing device main body 12 will be described.

In the printing device main body 12, each unit is provided in an interior 20a of a casing 20 such that the printing is carried out in a clean atmosphere. A filter (not illustrated) and air conditioning equipment (not illustrated) are provided such that the interior 20a of the casing 20 has a predetermined cleanliness.

The printing device main body 12 includes an image recording unit 22, a processing unit 23, a plate cylinder 24, a stage 30, a drying unit 32, an ionizer 33, a cleaning unit 34, a removal unit 35, and a maintenance unit 36.

The image recording unit 22, the drying unit 32, the ionizer 33, the cleaning unit 34, and the processing unit 23 are provided so as to surround the periphery of the surface 24a of the plate cylinder 24. The cleaning unit 34 is provided by being brought into contact with the surface 24a of the plate cylinder 24, and the cleaning unit 34 is provided on the upstream side of the ionizer 33 in a Y direction in which the plate cylinder 24 rotates. Further, the processing unit 23 is provided on the downstream side of the ionizer 33 in the Y direction and on the upstream side of the image recording unit 22 in the Y direction, and the processing unit 23 and the image recording unit 22 are separately provided.

The substrate 31 is disposed on the stage 30, and the printing plate 25 and the surface 31a of the substrate 31 are disposed to be in contact with each other in a case where the plate cylinder 24 rotates in a state in which the stage 30 is disposed at a printing position Pp below the plate cylinder 24. In this manner, the ink applied to the pattern formation region 27a which has been predetermined on the plate surface 25a of the printing plate 25 is transferred to the surface 31a of the substrate 31. A transfer unit 39 is formed of the plate cylinder 24 and the stage 30.

Further, in the printed substrate 31, the ink is fired, for example, by heat, light, or the like according to the characteristics of the ink. Known means used for firing the ink for which heat or light has been used can be appropriately used. The firing of the ink with respect to the substrate 31 can be carried out in the interior 20a or outside of the casing 20.

In the printing device 10, the ink is applied to the pattern formation region of the printing plate 25 provided on the plate cylinder 24, and the ink application may be carried out only once or over a plurality of times. In a case where the ink is applied over a plurality of times, the plate cylinder 24 is allowed to rotate the number of times to apply the ink. For example, in a case where the ink is applied over four times, the plate cylinder 24 is allowed to rotate four times. Application of the ink is referred to as inking. Further, among the plurality of times, performance of inking once is also referred to as scanning.

Hereinafter, each unit of the printing device main body 12 will be described.

The image recording unit 22 is a unit that applies the treatment liquid or the ink to the pattern formation region predetermined on the plate surface 25a of the printing plate 25, and the treatment liquid and the ink are applied to a pattern predetermined on the plate surface 25a by the image recording unit 22. Further, an image recording system of the image recording unit 22 is not particularly limited. For example, an ink jet method is used.

The plate cylinder 24 is capable of rotating in one direction, for example, the Y direction centering on a rotating shaft 24b. The Y direction is the rotation direction. Further, the Y direction is also referred to as a feed direction. Further, the plate cylinder 24 is used for transferring the ink of the plate surface 25a of the printing plate 25 applied to the predetermined pattern formation region 27a to the surface 31a of the substrate 31 by allowing the printing plate 25 to rotate in a state of holding the printing plate 25.

In the rotating shaft 24b, for example, a motor (not illustrated) for rotating the plate cylinder 24 is provided via a gear (not illustrated). Further, a direct drive motor can be provided without a gear. The motor is controlled by the control unit 18. Further, a rotary encoder (not illustrated) that detects rotation and the rotation amount is provided for the rotating shaft 24b. The rotary encoder is connected to the control unit 18, and the rotation amount of the plate cylinder 24 is detected by the control unit 18.

The substrate 31 to be transferred is not particularly limited, but a film substrate such as polyethylene naphthalate (PEN), polyethylene terephthalate (PET), or polycarbonate (PC), a glass epoxy substrate, a ceramic substrate, or a glass substrate can be used. As a method of transferring the substrate, in a case of a rigid substrate such as a glass substrate, the substrate 31 can be transferred by being fixed onto the stage 30 and being brought into close contact with the plate cylinder 24 as described above.

In a case where a film is used for the printing plate 25, an impression cylinder may be used. The substrate may be transferred by fixing the film to the impression cylinder and bringing the film into close contact with the plate cylinder 24.

The stage 30 places the substrate 31, moves in a transport direction V, and transports the substrate 31 to a predetermined position. A transport mechanism (not illustrated) is provided in the stage 30. Since this transport mechanism is connected to the control unit 18, the transport mechanism is controlled by the control unit 18 so that the stage 30 is moved in the transport direction V. Accordingly, the position of the stage 30 is changed.

First, the stage 30 stands by at a start position Ps on which the substrate 31 transported from the outside of the casing 20 is placed. Next, the stage 30 is moved to the printing position Pp below the plate cylinder 24. Next, after the printing, the stage 30 is moved to an end position Pe in a state of placing the printed substrate 31, and then the substrate 31 is taken out of the casing 20. The stage 30 is moved to the start position Ps from the end position Pe and stands by until the substrate 31 is carried in.

The drying unit 32 dries the ink on the plate surface 25a of the printing plate 25 and also dries the treatment liquid on the plate surface 25a of the printing plate 25. The drying unit 32 dries the ink and the treatment liquid on the plate surface 25a of the printing plate 25 and is required to dry until the ink is transferred to the substrate 31. Therefore, the drying unit 32 is provided between the image recording unit 22 and the transfer unit 39.

A drying method is not particularly limited as long as the drying unit 32 is capable of drying the ink and the treatment liquid. Examples of the drying method include blowing warm air or cold air using a fan, heating using an infrared heater, irradiation with high frequencies, and irradiation with microwaves.

Further, in a case where the ink on the plate surface 25a of the printing plate 25 can be naturally dried, the drying unit 32 is not necessarily provided.

Depending on the printing step, in some cases, the drying unit 32 dries the printing plate 25 to which only the treatment liquid described below has been applied without application of the ink to the printing plate 25.

The ionizer 33 removes static electricity of the plate surface 25a of the printing plate 25. The static electricity of the plate surface 25a of the printing plate 25 is removed by the ionizer 33, and adhesion of foreign matter such as dust or dirt to the plate surface 25a of the printing plate 25 is suppressed. Further, the plate surface 25a of the printing plate 25 is charged, the jetted ink may be bent. However, it is possible to prevent the jetted ink from being bent so that the ink jet jetting accuracy is improved.

Further, an electrostatic eliminator can be used for the ionizer 33, and a corona discharge method or an ion generation method can be used. Further, the ionizer 33 is provided on the downstream side of the cleaning unit 34 in the Y direction as described above. Therefore, even in a case where the plate surface 25a of the printing plate 25 in the cleaning unit 34 is charged with static electricity, the static electricity can be removed.

The cleaning unit 34 removes the ink adhered to the plate cylinder 24 and the printing plate 25. The configuration of the cleaning unit 34 is not particularly limited as long as the ink adhered to the plate cylinder 24 and the printing plate 25 can be removed. For example, a configuration in which a roller is pressed against the plate cylinder 24 so that the ink is transferred to the roller, and the transferred ink is wiped off may be employed.

The removal unit 35 removes the treatment liquid and the solvent of the ink described below applied to the printing plate 25. By removing the treatment liquid and the solvent of the ink, the ink can be more easily dried.

For example, a rotating roller (not illustrated) rotating about the rotating shaft is disposed in the removal unit 35 with respect to the printing plate 25. A web (not illustrated) for removing the treatment liquid and the solvent of the ink of the printing plate 25 is wound on the peripheral surface of the rotating roller. The web is not particularly limited as long as the treatment liquid and the solvent of the ink of the printing plate 25 can be removed.

With respect to the printing plate 25 from which the ink has been removed, for example, the treatment liquid and the solvent of the ink in a case of remaining are removed by directly coating the printing plate 25 with a removing liquid or directly spraying the removing liquid to the printing plate 25, allowing the rotating roller to rotate, and bringing the web into contact with the printing plate 25. Further, the treatment liquid and the solvent of the ink in a case of remaining may be removed by spraying a removing liquid to the web, allowing the rotating roller to rotate, bringing the web into contact with the printing plate 25.

As the removing liquid, for example, a volatile solvent such as acetone can be used.

Further, a configuration in which at least one of the drying unit 32 or the removal unit 35 is provided may be employed.

The maintenance unit 36 investigates whether performance in which the jetting characteristic or the like of the image recording unit 22 is predetermined is exhibited. Further, the maintenance unit 36 investigates whether performance in which the jetting characteristic or the like of the processing unit 23 is predetermined is exhibited.

The maintenance unit 36 performs wiping or the like on nozzles so that predetermined performance is exhibited. The maintenance unit 36 is provided at a position separated from the plate cylinder 24. The image recording unit 22 is transferred to the maintenance unit 36, for example, via a guide rail (not illustrated). Further, the processing unit 23 is transferred to the maintenance unit 36, for example, via the guide rail (not illustrated).

Hereinafter, the image recording unit 22 will be described in detail.

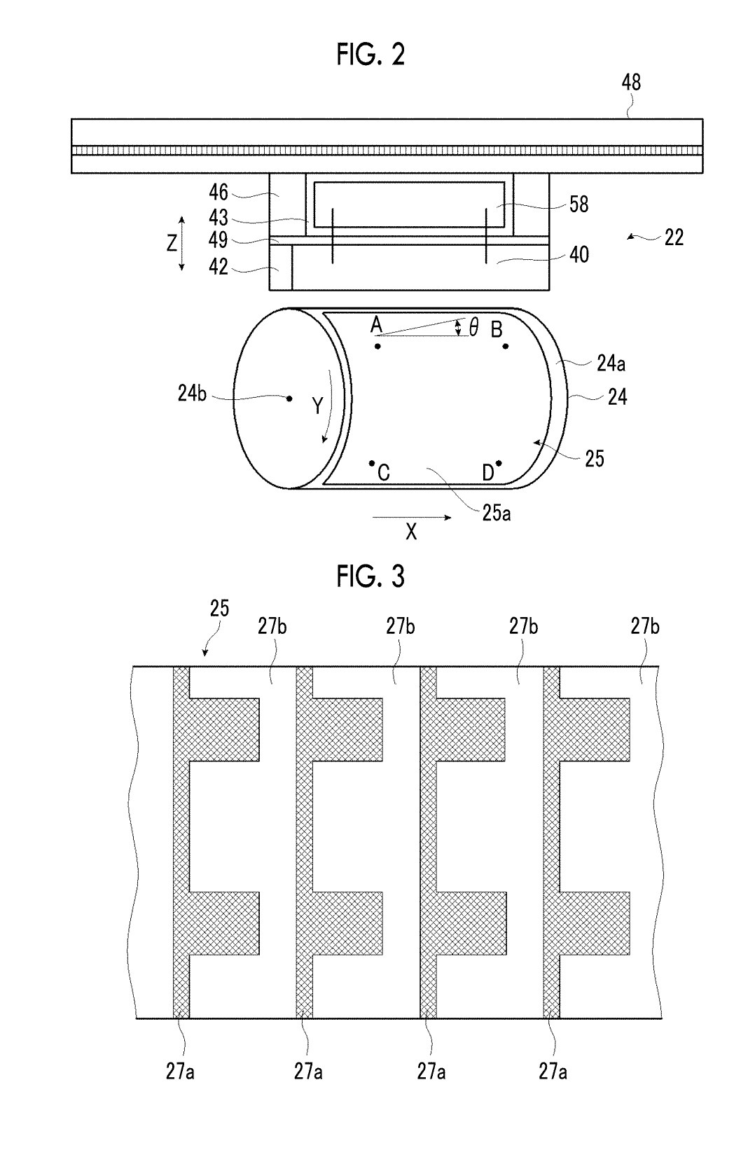

FIG. 2 is a schematic view illustrating an image recording unit of a printing device according to the embodiment of the present invention.

An example in which an ink jet method is used for the image recording unit 22 will be described.

As illustrated in FIG. 2, the image recording unit 22 includes an ink jet head 40, an alignment camera 42, and a revolving unit 49, and these members are provided on a carriage 46. The carriage 46 can be moved in a direction parallel to the rotating shaft 24b of the plate cylinder 24, that is, an X direction by a linear motor 48, and the ink jet head 40 can be moved in the X direction by the carriage 46. The position of the carriage 46 can be calculated from a read value of a linear scale (not illustrated) provided in the linear motor 48.

The ink jet head 40 is an ink applying unit, and a jetting control unit 43 is provided in the ink jet head 40 in order to control the jetting of the ink. The jetting waveform of the ink is adjusted by the jetting control unit 43. The jetting control unit 43 is connected to the control unit 18. In the jetting control unit 43, for example, the jetting voltage or the jetting waveform can be adjusted by a user via a user interface. Further, the ink is jetted in a state in which the temperature of the ink is adjusted as described below.

The alignment camera 42 is used for obtaining position information related to alignment marks for correcting the jetting position of the ink, the jetting timing of the ink, and the ink set pattern data of the ink.

The configuration of the alignment camera 42 is not particularly limited as long as alignment marks A to D can be detected.

The alignment marks A to D are imaged by the alignment camera 42, the imaging data is stored in the storage unit 14, and the positions of the alignment marks A to D are specified by the determination processing unit 16. The alignment camera 42 and the determination processing unit 16 function as an attachment position information acquisition unit that acquires attachment information related to the printing plate 25 provided on the plate cylinder 24.

Based on the position information related to the alignment marks A and B, information related to a jetting start position of the ink in the Y direction, expansion and contraction of the printing plate in the X direction, and an inclination angle θ of the printing plate can be obtained. Based on the position information related to the alignment marks A and C, information related to the jetting start position of the ink in the X direction and expansion and contraction of the printing plate in the Y direction can be obtained. Based on the position information related to the alignment marks A to D, for example, trapezoidal distortion information related to the printing plate, that is, trapezoidal deformation information can be obtained. The jetting start position of the ink is referred to as an inking start position.

In the printing plate 25, it is ideal that a line La (see FIG. 6) passing through the alignment mark A and the alignment mark C is parallel to the Y direction described above. However, the printing plate 25 is slightly inclined with respect to the plate cylinder 24 at the time of attachment of the printing plate 25 to the plate cylinder 24. Based on the position information related to the alignment marks A to D, attachment information related to the printing plate 25 onto the plate cylinder 24, for example, information related to the inclination of the printing plate 25 with respect to the Y direction of the plate cylinder 24 can be obtained.

Based on the various pieces of the obtained information, the jetting start position of the ink, the position of the ink jet head 40, and the jetting timing of the ink are corrected. For all these corrections, known correction methods for jetting an ink according to ink jet can be used.

Further, known correction methods can be used for expansion and contraction of the ink set pattern in the X direction, expansion and contraction thereof in the Y direction, the inclination, and the trapezoidal correction.

Further, the information related to the expansion and contraction of the printing plate in the X direction, the inclination angle θ of the printing plate, and the expansion and contraction of the printing plate in the Y direction can be obtained in a case where at least three alignment marks are present. From the viewpoint that the information on trapezoidal distortion of the printing plate 25 can be obtained in a case where four alignment marks are present, it is preferable that the number of alignment marks is four. Further, non-linear correction can be performed by providing a plurality of alignment marks inside the alignment marks A to D. In this case, correction using the alignment marks can be carried out according to known correction methods.

In the image recording unit 22, the application of the ink is not limited to the ink jet head 40. A method of using die coating or a method of using capillary coating may be performed.

FIG. 3 is a schematic view illustrating an example of the printing plate.

As illustrated in FIG. 3, the printing plate 25 is configured such that the plate surface 25a is divided into a predetermined pattern formation region 27a and a non-pattern formation region 27b other than the pattern formation region 27a. An ink is applied to the pattern formation region 27a to form a printing pattern.

The ink jet head 40 is used for jetting an ink and applying the ink to the pattern formation region 27a.

The system of jetting the ink of the ink jet head 40 is not particularly limited, and examples thereof include various systems such as a piezoelectric system of jetting a liquid using deflection deformation, shearing deformation, and longitudinal vibration of a piezoelectric element; a thermal system of jetting a liquid using a film boiling phenomenon by heating a liquid in a liquid chamber with a heater, and an electrostatic system using electrostatic force.

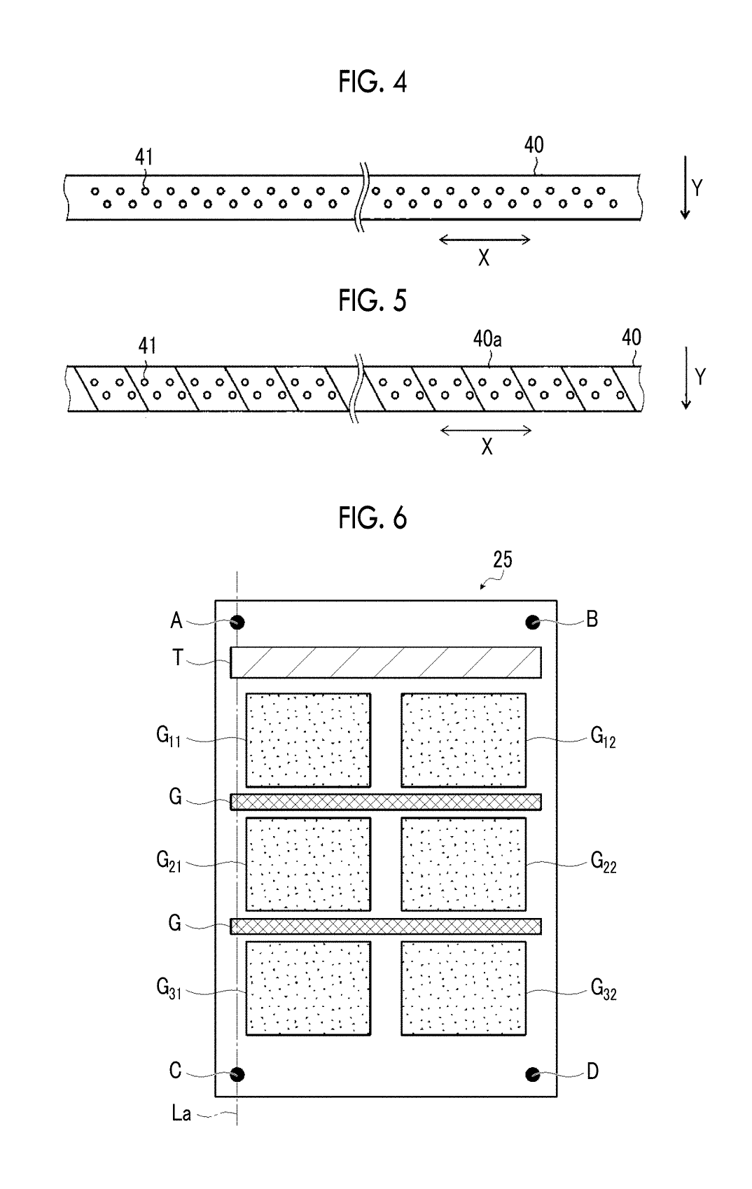

As a specific configuration of the ink jet head 40, a plurality of nozzles 41 are arranged in a staggered manner over the length corresponding to the total width of the printing plate 25 as illustrated in FIG. 4.

By applying the staggered arrangement, the nozzles 41 can be arranged at a high density. Further, the number of rows of the nozzles 41 to be arranged is not particularly limited, and one or two or more rows may be used. Further, the nozzles 41 may be arranged in a matrix shape.

The configuration of the ink jet head 40 is not particularly limited. For example, the configuration illustrated in FIG. 5 may be employed. A plurality of head modules 40a are connected to each other in the ink jet head 40 illustrated in FIG. 5 in the X direction. In this case, the present invention is not limited to the configuration in which the plurality of head modules 40a are connected to each other in one row, and a configuration in which a plurality of head modules 40a are connected to each other in a staggered manner may be employed.

In the ink jet head 40 illustrated in FIG. 5, the jetting waveform for each head module 40a can be adjusted by the jetting control unit 43. Further, in a case where the jetting control unit 43 is provided for each head module 40a, the jetting waveform for each jetting control unit 43 can be adjusted.

The processing unit 23 applies the treatment liquid to the pattern formation region 27a (see FIG. 3) in a preset treatment liquid set pattern. The processing unit 23 applies the treatment liquid to the pattern formation region 27a (see FIG. 3) in a treatment liquid set pattern before or after the ink is applied by the ink jet head 40. Accordingly, the processing unit 23 may be provided in a direction opposite to the Y direction with respect to the ink jet head 40 or provided in the Y direction of the ink jet head 40. Therefore, the number of the processing units 23 to be provided is not limited to one and may be two. Further, the timing for application of the ink and the timing for application of the treatment liquid may be the same as each other.

The processing unit 23 is provided separately from the image recording unit 22 as described above, but has the same basic configuration as the image recording unit 22 except for jetting of the treatment liquid. Accordingly, the detailed description will not be provided. The processing unit 23 includes a jet head 90 that jets the treatment liquid, the alignment camera 42, and the revolving unit 49, and these members are provided on a carriage (not illustrated).

The jet head 90 applies the treatment liquid according to, for example, the ink jet method. The jet head 90 has the same configuration as that of the ink jet head 40 described above. Further, the carriage has the same configuration as that of the carriage 46 (see FIG. 2) of the image recording unit 22 and can be moved in a direction parallel to the rotating shaft 24b of the plate cylinder 24, that is, the X direction by a linear motor (not illustrated) (see FIG. 2), and the jet head 90 can be moved in the X direction by the carriage. The position of the carriage can be calculated from a read value of a linear scale (not illustrated) provided in the linear motor (not illustrated).

The alignment camera 42 of the processing unit 23 has the same configuration as that of the alignment camera 42 of the image recording unit 22. The alignment camera 42 is used for obtaining position information related to alignment marks for correcting the jetting position of the treatment liquid, the jetting timing of the treatment liquid, and the treatment liquid set pattern data.

Based on the various pieces of the obtained information, the jetting start position of the treatment liquid, the position of the jet head 90, and the jetting timing of the treatment liquid are corrected. For all these corrections, known correction methods for jetting an ink according to ink jet can be used.

Further, in this case of the treatment liquid set pattern data, known correction methods can be used for expansion and contraction in the X direction, expansion and contraction in the Y direction, the inclination, and the trapezoidal correction.

The treatment liquid is used for increasing a second diameter of the ink after application of the treatment liquid compared to a first diameter of the ink landed on the pattern formation region 27a (see FIG. 3) without application of the treatment liquid. Here, the second diameter of the ink indicates the ink diameter after 5 seconds from the application of the treatment liquid. The second diameter is the length of the major axis of the ink diameter.

The treatment liquid causes wet-spreading of the ink and is different from an ink. Further, it is preferable that the treatment liquid is colorless and transparent. The term “colorless” here includes a state of being slightly colored even though not as colored as an ink, and it is preferable that the treatment liquid is completely colorless.

Further, it is desirable that the treatment liquid is not transferred to the substrate or disappears from the substrate after the formation of the wiring so that the function of the wiring is not affected by the treatment liquid. Therefore, it is desirable that the treatment liquid is absorbed by the printing plate, is not transferred to the substrate, and evaporates or sublimes in one hour when staying in an environment of a temperature of 180° C. or lower and desirably 120° C. or lower.

It is preferable that the treatment liquid has at least the same surface energy as that of the ink or the solvent of the ink. The surface energy of the treatment liquid is assumed to be the same as that of the ink or the solvent of the ink in a case where the values of the surface energy have an error range of ±10% with respect to the same value. Further, the surface energy is a value measured using a surface tension meter.

The treatment liquid is a solvent of an ink in a case where the ink contains a solvent. In this case, since the treatment liquid is the solvent of the ink, the surface energies thereof are the same as each other.

The processing unit 23 is not particularly limited as long as the treatment liquid can be applied to the pattern formation region 27a in a preset treatment liquid set pattern. For example, similar to the ink, the treatment liquid can be applied according to an ink jet method. The same structure as the ink jet head 40, that is, the configuration of the ink jet head 40 illustrated in FIGS. 4 and 5 can be used for the processing unit 23.

The treatment liquid can be easily applied according to the treatment liquid set pattern by using the processing unit 23 according to an ink jet head system. Further, the amount of the treatment liquid to be used can be easily changed according to the printing pattern. In addition, the treatment liquid can be applied even after the ink has been applied. Further, the amount of the treatment liquid to be used can be further reduced compared to a case where the treatment liquid is applied to the entire surface of the pattern formation region 27a by jetting the treatment liquid in a treatment liquid set pattern, that is, a case where the treatment liquid is so-called solidly applied. Further, since the amount of the treatment liquid to be used is small, the treatment liquid can be applied in a short time, and the time required for drying is reduced. Therefore, the productivity can be increased.

The processing unit 23 can perform application using a dispenser or the like according to a printing method such as gravure printing or offset printing other than the ink jet method. Further, the processing unit 23 performs application according to a method of using die coating or a method of using capillary coating.

Next, the printing plate 25 will be described in detail.

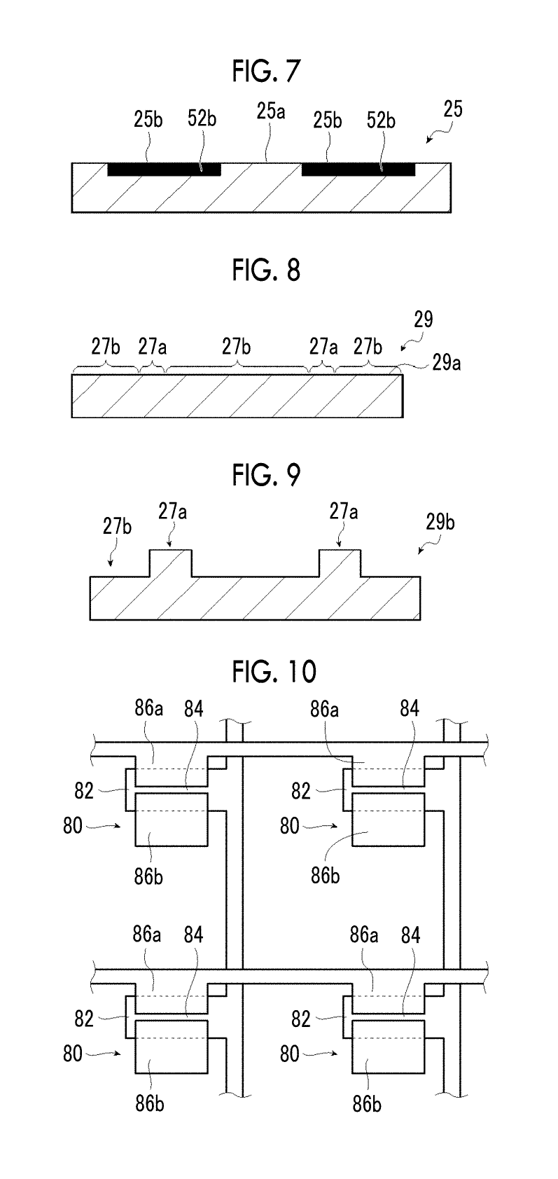

FIG. 6 is a schematic view illustrating an example of a printing plate used for the printing device according to the embodiment of the present invention. FIG. 7 is a schematic cross-sectional view illustrating an example of a printing plate used for the printing device according to the embodiment of the present invention. FIG. 8 is a schematic cross-sectional view illustrating a planographic plate which is a printing plate used for the printing device according to the embodiment of the present invention. FIG. 9 is a schematic cross-sectional view illustrating a relief printing plate which is a printing plate used for the printing device according to the embodiment of the present invention.

As illustrated in FIG. 6, for example, the alignment marks A to D are respectively provided at four corners of the printing plate 25, and a jetting confirmation area T, printing areas G₁₁ and G₁₂, a spit area G, printing areas G₂₁ and G₂₂, a spit area G, and printing areas G₃₁ and G₃₂ are formed on the printing plate 25.

Further, the liquid repellency with respect to the ink and lyophilicity with respect to the ink can be evaluated as described below.

By landing liquid droplets on a region expected to be liquid repellent and a region expected to be lyophilic, the evaluation is performed based on the behavior of the liquid droplets. The region where the amount of liquid droplets is reduced with respect to the amount of liquid droplets at the time of being landed is an ink-repellent portion having liquid repellency and a region where the amount of liquid droplets is increased is an ink-philic portion having lyophilicity.

In addition, the liquid repellency and the lyophilicity are imparted during a step of preparing a plate. In this case, by landing liquid droplets on the boundary between the ink-repellent portion having liquid repellency and the ink-philic portion having lyophilicity, the evaluation of the liquid repellency and the lyophilicity are evaluated based on the behavior of the liquid droplets. The region where the amount of liquid droplets is reduced with respect to the amount of liquid droplets at the time of being landed is a liquid-repellent region and a region where the amount of liquid droplets is increased is a lyophilic region.

In a case where the boundary between unevenness of the printing plate matches to the boundary between the ink-repellent portion having liquid repellency and the ink-philic portion having lyophilicity, the boundaries can be distinguished from each other based on the unevenness. In a case where the unevenness of the printing plate is small and the boundaries are unlikely to be distinguished from each other, a change in the amount of liquid droplets in the boundary can be evaluated by landing a plurality of liquid droplets in the vicinity of the boundary. Further, it is possible to know the boundaries by providing alignment marks indicating the boundary between unevenness of the printing plate.

As the material of the printing plate 25, a resin, a metal, or glass may be used without limitation. However, in a case where a resin plate is used, it becomes easy to perform printing on a brittle material such as glass since because the elasticity is ensured and the printing pressure can be decreased. As the material of the printing plate 25, various elastomers such as fluorosilicone rubber, butyl rubber, ethylene propylene rubber, nitrile rubber, neoprene rubber, hypalon rubber, and urethane rubber can be used, and silicone rubber such as polydimethylsiloxane (PDMS) with excellent release properties and fluorine rubber are desirable. In a case where polydimethylsiloxane (PDMS) is used, the transfer properties are improved, remaining of the ink on the printing plate 25 after the transfer is suppressed, and continuous printing can be carried out even in a case where the printing plate 25 is not clean. In this manner, the printing efficiency can be improved.

Further, for example, an intaglio plate in which depressions 25b illustrated in FIG. 7 have been formed is used as the printing plate 25. In addition, the depressions 25b are formed like the predetermined pattern formation region 27a (see FIG. 3) according to a known method.

The printing plate 25 is not limited to the intaglio plate as long as the pattern formation region 27a is divided from the non-pattern formation region 27b, and the printing plate 25 may be a planographic plate 29 illustrated in FIG. 8. The planographic plate 29 has a flat surface 29a, and the pattern formation region 27a and the non-pattern formation region 27b are divided from each other based on the lyophilicity and the liquid repellency with respect to the ink. The pattern formation region 27a is a lyophilic portion having lyophilicity with respect to the ink and the non-pattern formation region 27b is a liquid-repellent portion having liquid repellency with respect to the ink.

The printing plate 25 may be a relief printing plate 29b illustrated in FIG. 9. In this case, a projection is a lyophilic portion having lyophilicity with respect to the ink, which is the pattern formation region 27a. Further, portions other than the projection are a liquid-repellent portion having liquid repellency with respect to the ink, which is the non-pattern formation region 27b.

Next, the maintenance unit 36 will be described in detail.

The maintenance unit 36 includes a wipe unit that removes the ink, dust, and the like adhered to the ink jet head 40 using a web (not illustrated) or a rubber blade (not illustrated).

For example, the web is wound on the peripheral surface of the rotating roller, allows the rotating roller to rotate so that the web comes into contact with the ink jet head 40, and wipes off the ink, dust, and the like. The web is not particularly limited to being wound on the peripheral surface of the rotating roller as long as the ink, dust, and the like adhered to the ink jet head 40 can be removed. As the web, usually, so-called wiping cloth can be appropriately used.

For example, the ink, dust, and the like adhered to the ink jet head 40 may be removed by directly applying a cleaning solution to the ink jet head 40 using a web provided with a cleaning solution.

As the cleaning solution, for example, a solvent having solubility in an ink or a solution that does not contain solid contents from among ink components is used or a hydrocarbon-based solvent can be used. Examples of the hydrocarbon-based solvent include toluene, xylene, hexane, tetradecane, and cyclododecene.

In the wipe unit formed by using a rubber blade, the rubber blade is fixed and the ink jet head 40 is moved in the X direction using the fact that the ink jet head 40 can be moved in the X direction by the carriage 46, and the ink is wiped in the longitudinal direction. The ink may be wiped by fixing the ink jet head 40 and moving the rubber blade in the X direction. The above-described cleaning solution can be used in a case where the rubber blade is used. In addition, the maintenance unit 36 may include a cap (not illustrated) in order to prevent the nozzles 41 from being dried.

The maintenance unit 36 is capable of allowing the ink jet head 40 to perform an operation such as purging, spitting, or dripping.

The purging indicates pushing the ink out from the nozzles 41 by disposing the ink jet head 40 on an ink receiver (not illustrated).

The spitting is an operation of jetting. Through the spitting, nozzle clogging or jet bending can be improved. Further, the spitting is performed at the same place as that of the purging, but a station for spitting may be provided.

The dripping is not a recovery operation for pushing out the ink as strongly as the above-described purging operation does but an operation of performing recovery by allowing the ink to slowly drip. In this manner, nozzle clogging or jet bending of the ink can be improved.

Further, the maintenance unit 36 may be configured to include a jetting observation unit (not illustrated) that observes ink droplets 45 jetted from the ink jet head 40; and a nozzle observation unit (not illustrated) that observes nozzles 41 (see FIG. 4) of the ink jet head 40 from the surface side on which the nozzles 41 are formed.

Both of the jetting observation unit and the nozzle observation unit are connected to the control unit 18 so that these operations are controlled by the control unit 18 and the obtained imaging data is stored in the storage unit 14 by the control unit 18. The jetting state of the ink from the ink jet head 40 is compared with design values of the jetting characteristics of the ink jet head 40 by the control unit 18, and the comparison results are stored in the storage unit 14.

Further, the maintenance unit 36 performs the same operation on the processing unit 23 including the jet head 90 as the operation performed on the ink jet head 40.

For example, a gate electrode, a source electrode, and a drain electrode of a thin film transistor used for electronic paper or the like can be prepared by the printing device 10 of the present invention.

FIG. 10 is a schematic view illustrating an example of a thin film transistor to be formed by the printing device according to the embodiment of the present invention.

The thin film transistor 80 (hereinafter, also referred to as a TFT 80) illustrated in FIG. 10 includes a gate electrode 82, a gate insulating layer (not illustrated), a source electrode 86a, a drain electrode 86b, a semiconductor layer (not illustrated), and a protective layer (not illustrated).

The gate insulating layer (not illustrated) is formed on the TFT 80 so as to cover the gate electrode 82. The source electrode 86a and the drain electrode 86b are formed on the gate insulating layer with a preset gap as a channel region 84. A semiconductor layer (not illustrated) functioning as an active layer is formed on the channel region 84. A protective layer (not illustrated) that covers the semiconductor layer, the source electrode 86a, and the drain electrode 86b is formed. Further, the channel length of the channel region 84 is in order of several micrometers to several tens of micrometers. The drain current of the thin film transistor affected by the channel length, and the variation in channel length leads to variation in characteristics of the thin film transistor.

Further, the printing method to be performed using the printing device 10 can be applied to production of electronic devices such as an electroluminescent transistor, an organic electroluminescence element, and a solar cell; and formation of an electrode such as the above-described electronic device, in addition to the TFT 80 illustrated in FIG. 10.

Hereinafter, a treatment performed using a treatment liquid will be described.

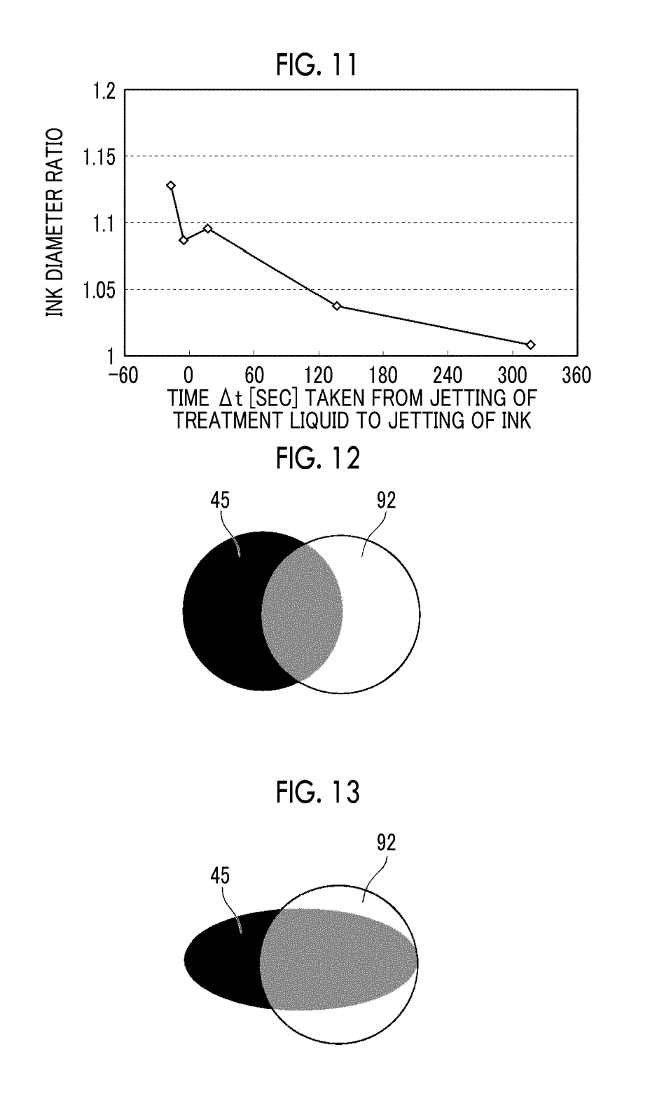

FIG. 11 is a graph showing the relationship between an ink diameter ratio and a time taken from jetting of the treatment liquid to jetting of the ink. FIGS. 12 and 13 are schematic views for describing an interaction between the ink and the treatment liquid.

In FIG. 11, the ink diameter ratio of the vertical axis indicates a ratio normalized by the ink diameter in a state in which the treatment liquid has not been applied. In the horizontal axis, the negative value indicates that the ink is landed earlier than the treatment liquid and the positive values indicate that the ink is landed after the treatment liquid.

As illustrated in FIG. 11, the ink droplets become larger than a case where the treatment liquid has not been applied regardless of the fact that the treatment liquid is landed earlier than the ink or the treatment liquid is landed after the ink. It was confirmed that the ink diameter of the ink droplets can be increased by the treatment liquid and the wettability of the ink droplets can also be increased. Further, it was confirmed that the ink diameter of the ink droplets is increased even after 300 seconds have elapsed after the application of the treatment liquid. The effect of expanding the wettability is decreased with time Δt seconds, and the reason for this is considered that the treatment liquid is absorbed by polydimethylsiloxane (PDMS) constituting the printing plate, and the treatment liquid evaporates so that the amount of the treatment liquid on the printing plate surface is reduced.

The results illustrated in FIG. 11 are obtained by using Ag Nano-Metal Ink, (L-AglteH (model number, silver content of 35% by mass, manufactured by ULVAC, Inc.) as the ink. Tetradecane is used as the treatment liquid. The printing plate is prepared by performing a step of mixing, defoaming, and applying two liquid types of polydimethylsiloxane (PDMS) (X-32-3279 (prototype No.), manufactured by Shin-Etsu Chemical Co., Ltd.) and X-32-3094-2 (prototype No.), curing the resultant at room temperature for 24 hours, immersing the resultant in isopropyl alcohol (IPA), eluting non-polymer components, and performing drying. In actual printing, since the solvent in the ink permeates into the printing plate by overlapping printing, the printing plate is immersed in the treatment liquid in advance, and then the ink droplets 45 are landed on the printing plate.

As illustrated in FIG. 12, in a case where a treatment liquid droplet 92 is applied to the ink droplet 45 due to the deviation of the landing position, the ink droplet 45 moves to the treatment liquid droplet 92 as illustrated in FIG. 13 so that the diameter of the ink droplet 45 is increased. In a case where the landing position of the ink droplet 45 is deviated from the landing position of the treatment liquid droplet 92, the ink droplet 45 is attracted to the treatment liquid droplet 92 which is landed later. In this manner, it was found that the size of the diameter of the ink droplet 45 depends on the positions of the ink droplet 45 and the treatment liquid droplet 92. In a case where the landing positions of the ink droplet 45 and the treatment liquid droplet 92 can be controlled with high accuracy, it is possible to cause wet-spreading of the ink droplet 45. The wettability of the ink droplet 45 is improved by applying the treatment liquid.

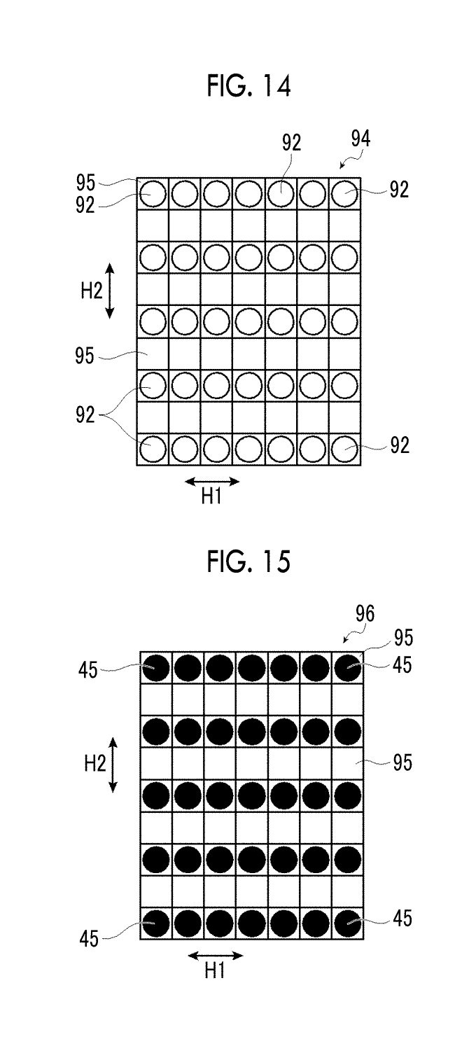

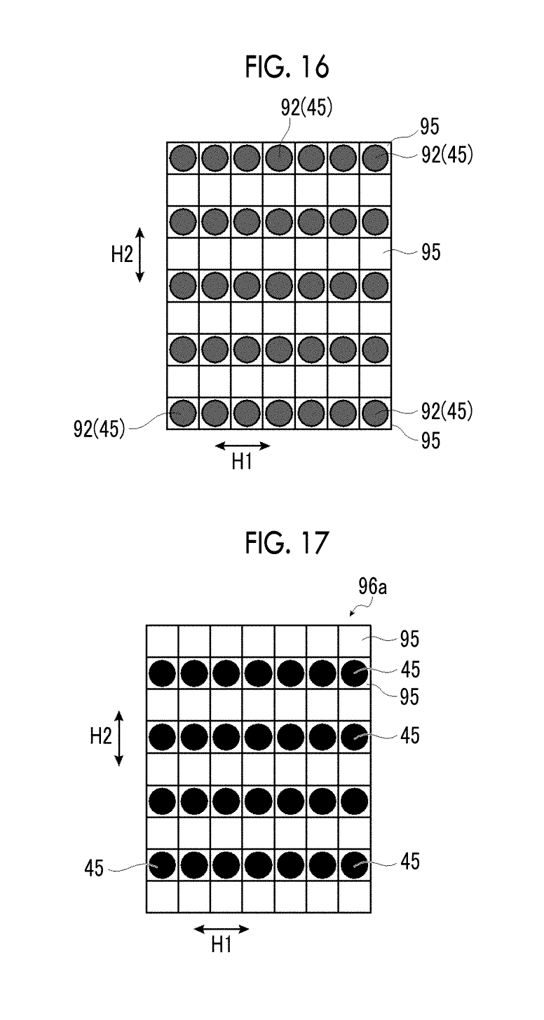

FIG. 14 is a schematic view illustrating a treatment liquid set pattern, FIG. 15 is a schematic view illustrating an ink set pattern of an ink, and FIG. 16 is a schematic view illustrating the treatment liquid set pattern and the ink set pattern of the ink.

For example, the treatment liquid is applied to the pattern formation region 27a (see FIG. 3) by the processing unit 23 in a treatment liquid set pattern 94 illustrated in FIG. 14. The treatment liquid set pattern 94 is a pattern in which the treatment liquid droplets 92 are landed continuously in a first direction H1 and in every other lattice 95 in a second direction H2 orthogonal to the first direction H1, in a plurality of lattices 95 arranged in the first direction H1 and in the second direction H2.

The ink set pattern 96 of the ink is the same pattern as the treatment liquid set pattern 94. For this reason, the detailed description of the ink set pattern 96 will not be provided.

Since the treatment liquid set pattern 94 and the ink set pattern 96 are the same as each other, the treatment liquid droplets 92 and the ink droplets 45 are landed in the same positions as illustrated in FIG. 16. In this case, the treatment liquid droplets 92 and the ink droplets 45 are landed in the same lattices 95.

The ink droplets 45 are allowed to wet-spread by the treatment liquid droplets 92. Further, the interval of the treatment liquid droplet 92 in the second direction H2, that is, the length of the lattice 95 in the second direction H2 is appropriately determined according to the extent of the wet-spreading of the ink droplets 45. For example, the ink droplets 45 wet-spread and the length thereof is set to be the united length in the second direction H2.

The same pattern indicates that the landing position of the treatment liquid is the same as the landing position of the ink droplets. As illustrated in FIG. 16, the treatment liquid droplets and the ink droplets are landed in the same lattices 95.

The pattern is not limited to the ink set pattern 96 illustrated in FIG. 15, and an ink set pattern 96a illustrated in FIG. 17 may be used. The ink set pattern 96a is a pattern which is different from the ink set pattern 96 illustrated in FIG. 15 and different from the treatment liquid set pattern 94.

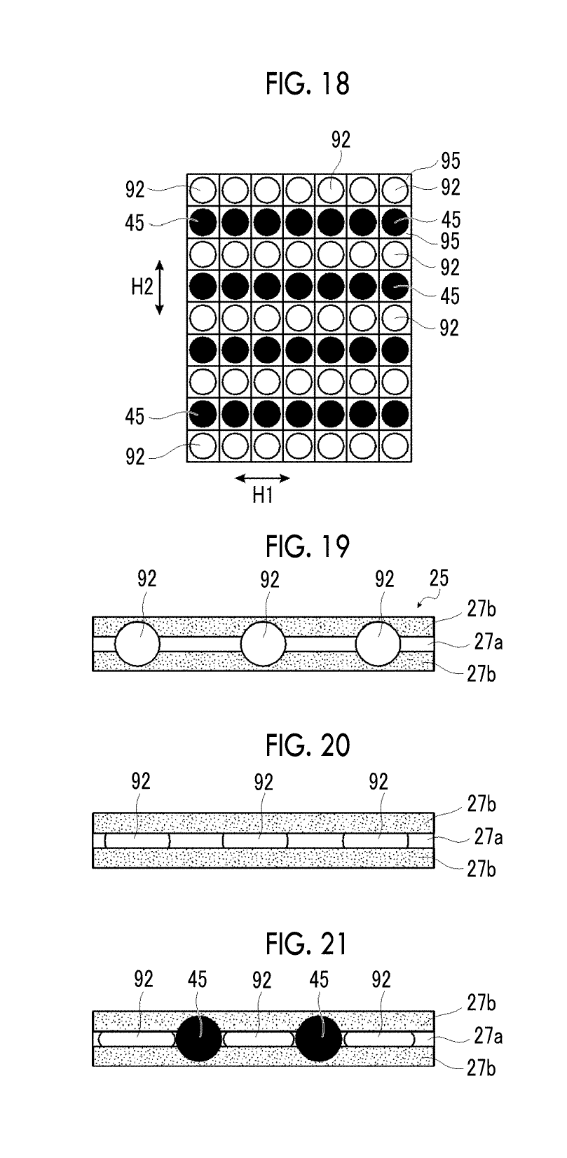

Different patterns indicate that the landing positions of the treatment liquid droplets 92 and the ink droplets 45 have different combinations. In this case, the treatment liquid droplets 92 and the ink droplets 45 are landed in different lattices 95 as illustrated in FIG. 18 and are not landed in the same lattices 95.

The ink set pattern 96a is a pattern in which the ink droplets 45 are landed in the lattices 95, in which the treatment liquid droplets 92 are not landed in the case of the treatment liquid set pattern 94 illustrated in FIG. 14. The ink set pattern 96a is a pattern in which the positions of the ink droplets 45 are deviated by one row of lattices 95 in the second direction H2, and the interval of the ink droplets 45 in the second direction H2 is the same as the interval of the treatment liquid droplets 92 of the treatment liquid set pattern 94.

In a case where the ink droplets 45 are applied in the ink set pattern 96a with respect to the treatment liquid set pattern 94, as illustrated in FIG. 18, the landing position of the treatment liquid droplets 92 is different from the landing position of the ink droplets 45 so that the treatment liquid droplets 92 and the ink droplets 45 do not overlap with each other and the ink droplets 45 are in a state of being interposed between treatment liquid droplets 92 in the second direction H2. Even in this case, the ink droplets 45 are attracted to the treatment liquid droplets 92 as illustrated in FIG. 13, and the wettability of the ink droplets 45 is improved by the surrounding treatment liquid droplets 92.

Further, at least a part of the ink set pattern may overlap with at least a part of the treatment liquid set pattern. Even in this case, the wettability of the ink droplets 45 is improved by the surrounding treatment liquid droplets 92.

The interval of the treatment liquid set pattern 94 in the second direction H2 is appropriately determined according to the extent of the wet-spreading of the ink droplets 45. For example, the ink droplets 45 wet-spread and are set to have a united length in the second direction H2.

For example, under a condition in which Δt illustrated in FIG. 11 is set to 17 seconds, in a case where the treatment liquid and the ink are landed on the printing plate by changing the distance between droplets under a condition in which the treatment liquid is present or under a condition in which the treatment liquid is not present, it was confirmed that three kinds of distances, which are a united distance even in a case where the treatment liquid is present or absent, a non-united distance even in a case where the treatment liquid is present or absent, and a distance which is united in a case where the treatment liquid is present and is not united in a case where the treatment liquid is absent are present.

Further, the conditions of all the printing plate, the treatment liquid, and the ink are the same as the conditions of FIG. 11 described above.

Regardless of the condition that the treatment liquid droplets 92 and the ink droplets 45 are landed on the same position or the condition that the treatment liquid droplets 92 and the ink droplets 45 are landed on different positions, since the amount of the treatment liquid to be used is smaller than the amount of the treatment to be used in a case where the treatment liquid is applied to the entire surface of the pattern formation region 27a, the time for drying the treatment liquid is decreased so that the productivity is improved. Further, compared to the case where the treatment liquid is applied to the entire surface of the pattern formation region 27a, the amount of the treatment liquid to be used can be reduced.

The amount of the treatment liquid to be used can be changed by controlling the jetting from the ink jet head and adjusting the nozzle diameter of the ink jet head. In a case where the amount of the treatment liquid to be used is increased, the effect of wet-spreading can be increased, but the above-described problem of drying occurs. Therefore, it is preferable that the amount of the treatment liquid to be used is set to the amount of the lower limit at which the effect of wet-spreading can be obtained, and the amount thereof is appropriately determined according to the required accuracy or the like for the printing.

Next, the printing method will be described.

FIGS. 19 to 23 are schematic views illustrating a first printing method according to the embodiment of the present invention in order of steps, and FIGS. 24 to 29 are schematic cross-sectional views illustrating the first printing method according to the embodiment of the present invention in order of steps. FIGS. 19 to 23 correspond to FIGS. 25 to 29, and a series of steps of the printing method are shown therein.

According to the first printing method, as illustrated in FIG. 19, the pattern formation region 27a having lyophilicity with respect to the ink and the non-pattern formation regions 27b having liquid repellency with respect to the ink are formed on the printing plate 25, and a linear pattern formed by interposing the pattern formation region 27a between the non-pattern formation regions 27b will be described as an example.

In this set pattern, the treatment liquid is jetted to the pattern formation region 27a at intervals so that the treatment liquid droplets 92 are landed as illustrated in FIGS. 19 and 26. After the treatment liquid droplets 92 are landed, the treatment liquid droplets 92 wet-spread over the pattern formation region 27a as illustrated in FIGS. 20 and 27.

Next, in the ink set pattern, the ink is jetted to the space between the pattern formation region 27a and the treatment liquid droplets 92 so that the ink droplets 45 are landed between the treatment liquid droplets 92 as illustrated in FIGS. 21 and 27. At this time, in a case where polydimethylsiloxane (PDMS) is used for the printing plate 25, the treatment liquid droplets 92 which have been wet-spreading are absorbed by the printing plate 25 and then evaporated.

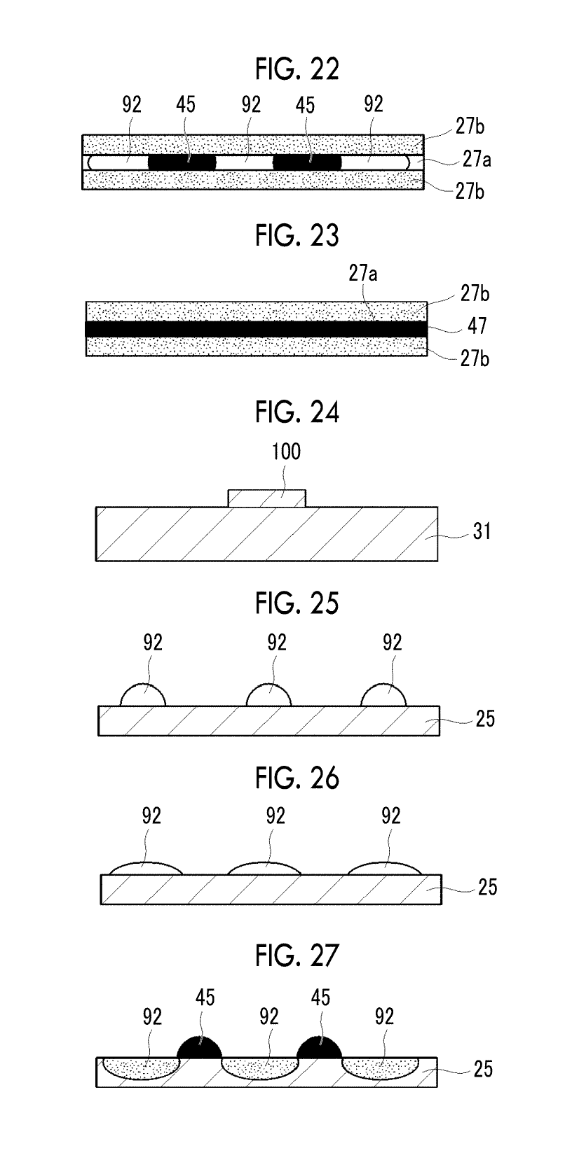

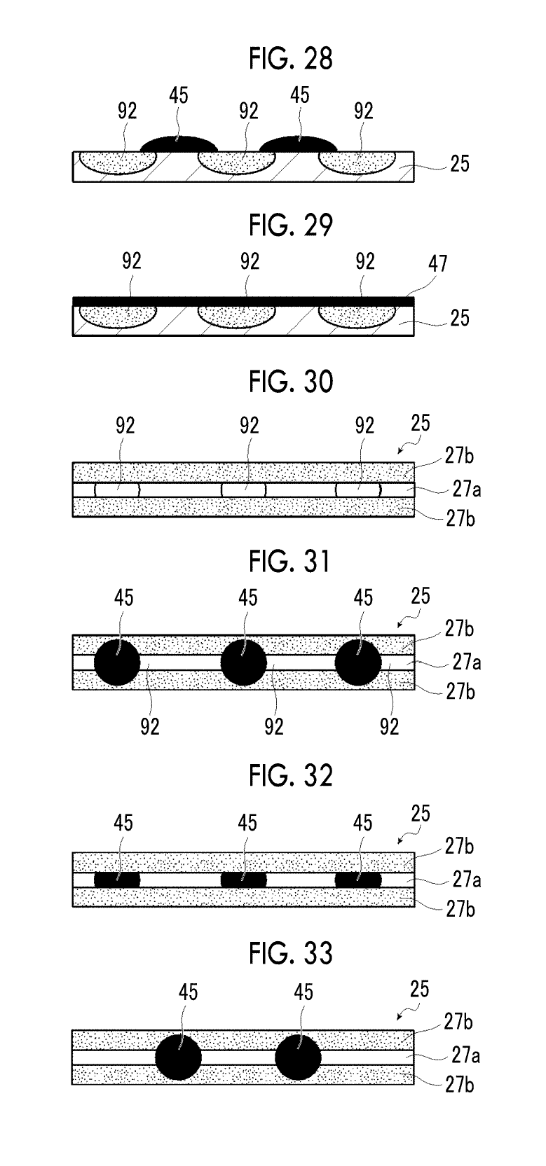

After the jetting, the ink droplets 45 wet-spread due to the treatment liquid droplets 92 as illustrated in FIGS. 22 and 28. Further, the ink droplets 45 are united to become an ink 47 in a linear pattern based on the pattern formation region 27a as illustrated in FIGS. 23 and 29. The ink 47 in a wiring pattern is dried, and the ink 47 of the printing plate 25 is transferred to the substrate 31 (see FIG. 1). In this manner, a wiring pattern 100 is formed on the substrate 31 as illustrated in FIG. 24.

According to the printing device 10 and the printing method, the wiring pattern 100 based on the pattern formation region 27a of a linear pattern is obtained. Therefore, according to the printing device 10 and the printing method, a high-definition printing pattern can be obtained by forming a high-definition pattern in the pattern formation region 27a of the printing plate 25, and thus the printing accuracy can be improved.

Since the treatment liquid is applied in the above-described treatment liquid set pattern 94 (see FIG. 14), the amount of the treatment liquid to be used can be reduced compared to the case where the treatment liquid is applied to the entire surface of the pattern formation region 27a. Further, the treatment liquid can be applied in a short time because the amount of the treatment liquid to be used is small, and thus the time required for the drying is reduced. Therefore, the time required for the printing can be reduced, and thus the productivity is improved. Further, since the amount of the treatment liquid to be used can be reduced, in a case where the amounts of the treatment liquid to be used are set to be the same as each other, images can be printed more than the case where the treatment liquid is applied to the entire surface of the pattern formation region 27a. Therefore, the productivity is high even from this viewpoint.

The first printing method illustrated in FIGS. 19 to 29 corresponds to a pattern in which the treatment liquid set pattern 94 is different from the ink set pattern 96a. However, as described above, the treatment liquid set pattern 94 may be the same as the ink set pattern 96. In this case, the ink droplets are jetted toward the treatment liquid droplets 92 in a state in which the treatment liquid droplets 92 have been wet-spreading according to a second printing method illustrated in FIG. 30, and the ink droplets 45 are landed on the treatment liquid droplets 92 which have been wet-spreading as illustrated in FIG. 31. In addition, as illustrated in FIG. 32, the ink droplets 45 wet-spread due to the treatment liquid droplets 92. Thereafter, as illustrated in FIG. 23, the ink droplets 45 are united to become the ink 47 in a linear pattern. Further, the ink 47 in a wiring pattern as described above is dried, and the ink 47 is transferred to the substrate 31 of the printing plate 25. In this manner, the wiring pattern 100 is formed on the substrate 31 as illustrated in FIG. 24.

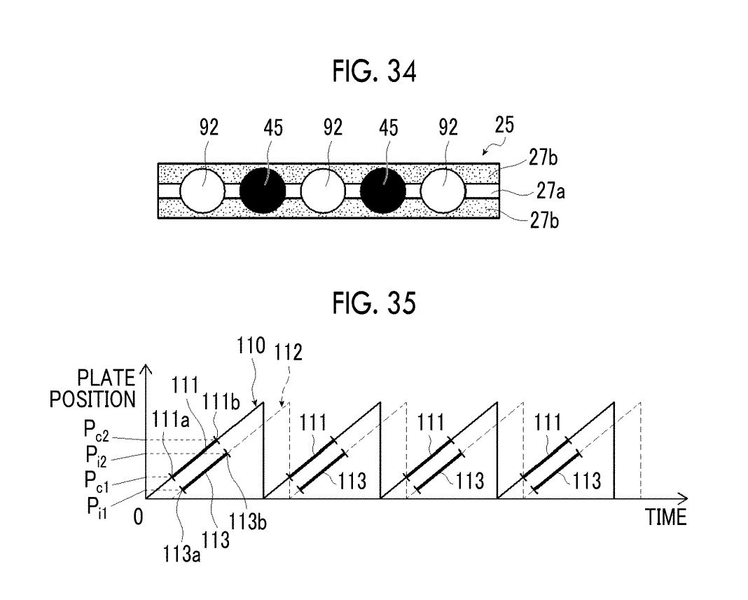

According to the first printing method, the treatment liquid droplets 92 are applied earlier than the ink droplets 45, but the present invention is not limited thereto. For example, the treatment liquid droplets 92 may be applied after the application of the ink droplets 45. In this case, the ink is jetted to the pattern formation region 27a of the printing plate 25 at intervals in the ink set pattern so that the ink droplets 45 are landed according to a third printing method illustrated in FIG. 33. Next, the treatment liquid droplets 92 are landed on the pattern formation region 27a so as to interpose the ink droplets 45 in the set pattern as illustrated in FIG. 34. Thereafter, the ink droplets 45 wet-spread due to the treatment liquid droplets 92, are united, and become the ink 47 in a linear pattern based on the pattern formation region 27a as illustrated in FIG. 23. The ink 47 in the wiring pattern is dried, and the ink 47 is transferred to the substrate 31 of the printing plate 25. In this manner, the wiring pattern 100 is formed on the substrate 31 as illustrated in FIG. 24.

In FIGS. 30 to 34, the same elements as those in the schematic views for describing the first printing method illustrated in FIGS. 19 to 23 are denoted by the same reference numeral, and the detailed description thereof will not be provided.

In the wiring pattern 100 formed in the above-described manner, it was found that the shape of the ink before being transferred onto the printing plate 25 is transferred to a surface 31a of the substrate 31 as it is. For example, in a case where the ink has a shape in which the center of the printing plate 25 has a depression which is a so-called coffee stain shape, the wiring pattern has a shape in which the center of the substrate 31 has a depression which is a so-called coffee stain shape.

Since the wiring pattern 100 is formed by being transferred to the substrate 31 from the plate cylinder 24, the wiring pattern 100 was considered to have a shape in which the shape of the printing plate 25 is reversed, but this did not actually happen. The mechanism of the transfer to the substrate 31 is not clear, but it is considered that polydimethylsiloxane (PDMS) is deformed due to the printing pressure at the time of the transfer in a case where polydimethylsiloxane (PDMS) is used for the printing plate 25 so that the substrate, the ink, and the printing plate come into close contact to one another. It is suggested that the cross-sectional shape of the wiring pattern can be freely controlled by controlling the shape of the ink on the printing plate before being transferred.

The coffee stain is known to be controlled by changing the volatile state of the ink, and the shape according to the specification of the wiring pattern can be achieved by ink design. Further, polydimethylsiloxane (PDMS) is known to absorb a solvent. Accordingly, the same effect can be obtained by controlling this absorption amount. Further, since the volatile state of the ink can be changed by the treatment liquid on the printing plate, the ink shape can be controlled by controlling the treatment liquid.

Next, the printing method according to the present embodiment will be described in detail using the printing device 10.

FIG. 35 is a timing chart showing the timing for application of the treatment liquid and the ink according to the printing method of the embodiment of the present invention. An example in which the plate cylinder 24 is allowed to rotate, for example, four times, the treatment liquid is first applied to the pattern formation region 27a (see FIG. 3) in the treatment liquid set pattern 94 (see FIG. 14) for each rotation, and the ink is applied to the pattern formation region 27a (see FIG. 3) in the ink set pattern 96 (see FIG. 15) is described. In FIG. 35, the plate position indicates a relative position between the plate cylinder 24 and the processing unit 23 and indicates a relative position between the plate cylinder 24 and the image recording unit 22. In a case where the plate position is 0, this indicates an initial position of the printing plate 25.

In FIG. 35, the reference numeral 110 represents a change in time of a relative position between the plate cylinder 24 and the processing unit 23 and the reference numeral 112 indicates a change in time of a relative position between the plate cylinder 24 and the image recording unit 22. The reference numeral 111 represents a period for application of the treatment liquid. The reference numeral 111a represents a start position and the reference numeral 111b represents an end position. A period 111 for application of the treatment liquid corresponds to a start position P_{c1} to an end position P_{c2} as indicated by the plate position.

The reference numeral 113 represents a period for application of the ink, the reference numeral 113a represents a start position, and the reference numeral 113b represents an end position. A period 113 for application of the ink corresponds to a start position Pᵢ₁ to an end position Pᵢ₂ as indicated by the plate position. Further, the above-described start positions Pc₁, the end position Pc₂, and the start position Pi₁, and the end position Pie can be calculated from rotation position information on the plate cylinder 24 output from a rotary encoder (not illustrated) provided on the plate cylinder 24.

In the processing unit 23, in a case where the plate reaches the start position P_{c1} of the treatment liquid, the application of the treatment liquid is started based on the treatment liquid set pattern, and the jetting of the treatment liquid is terminated when the plate reaches the end position P_{c2}. In a case where the plate reaches the start position pᵢ₁ of the ink in parallel with the application of the treatment liquid, the jetting of the ink is started based on the ink set pattern, and the jetting of the ink is terminated when the plate reaches the end position Pᵢ₂. Further, the order of the treatment liquid and the ink may be changed so that the ink may be applied earlier and then the treatment liquid may be applied.

For example, in a case where the ink set pattern data is at 2400 dpi (dot per inch), application of the ink, that is, inking to the pattern formation region can be completed by scanning a pattern at 1200 dpi in both of the X direction and the Y direction four times and scanning a pattern at 600 dpi in the X direction and 2400 dpi in the Y direction four times.

Moreover, for example, in a case of 1200 dpi in both of the X direction and the Y direction, twice the number of nozzles is required compared to a case of 600 dpi in the X direction even through the distance (minimum value) between adjacent pixels of one nozzle is 21.2 μm and the requirement for the jetting frequency is low. The distance between adjacent pixels in the X direction, that is, the minimum value becomes 21.2 μm. Accordingly, there is a concern about the landing interference in the X direction.

Meanwhile, in a case of 600 dpi in the X direction and 2400 dpi in the Y direction, the number of nozzles becomes ½ compared to the case of 1200 dpi in the X direction described above. Further, the distance between adjacent pixels in the X direction becomes 42.3 μm, and thus the influence of the landing interference in the X direction is decreased. However, the distance between adjacent pixels in the Y direction, that is, the minimum value becomes 10.6 μm, and it becomes necessary to jet twice the high frequency compared to the case of 1200 dpi in the X direction and the Y direction.

Next, the printing method of the printing device 10 according to the present embodiment will be described in more detail.

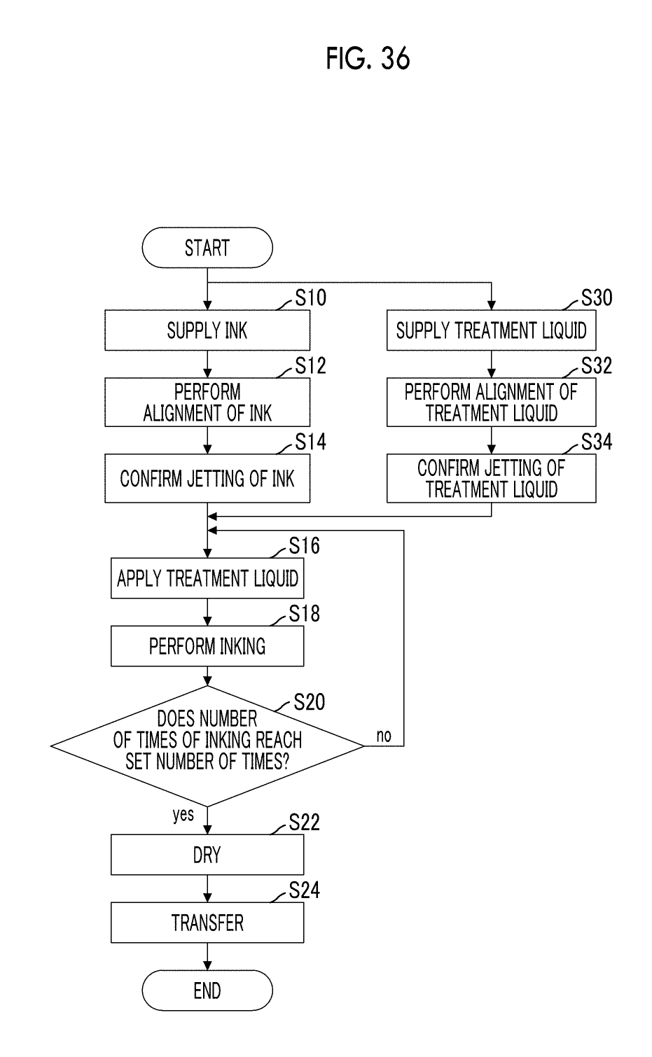

FIG. 36 is a flowchart showing the printing method according to the embodiment of the present invention.

First, the ink is supplied to an ink tank (Step S10). In Step S10, first, the ink (not illustrated) is sent from the ink tank (not illustrated) to a sub tank. In addition, the ink is supplied from the sub tank to the ink jet head 40.

Further, the cleaning solution is substituted with the ink at the time of supplying the ink. The ink can be supplied after the cleaning solution is jetted from the ink jet head 40 using nitrogen gas, but the nitrogen gas is easily mixed. Therefore, it is preferable that the supply of the ink is carried out by substitution from the cleaning solution.

In a state in which the cleaning solution is supplied to the ink jet head 40, the jetting confirmation is performed. In a case where the result is not desirable at the time of jetting confirmation, jetting recovery is performed using the maintenance unit 36. In a case where the jetting cannot be recovered, the ink jet head 40 is replaced as necessary.

At the time of substitution of the cleaning solution with the ink, for example, the amount of the cleaning solution of the sub tank is reduced to the lower limit. Next, the ink is added to the sub tank, and the cleaning solution in the ink jet head 40 is washed away by the ink. Next, the amount of the ink in the sub tank is reduced to the lower limit. The cleaning solution is substituted with the ink by repeatedly performing the process of washing the cleaning solution away from in the ink jet head 40 using the ink and reducing the amount of the ink in the sub tank to the lower limit.

Next, alignment is performed (Step S12).

In this case, the position of the ink jet head 40 and the plate position are aligned. First, the alignment marks A to C are read by the alignment camera 42 to detect the positions.

Next, the absolute distance in the X direction is acquired. In this case, for example, the absolute distance is calculated from the position of the carriage 46 in a case where the alignment mark A and the alignment mark B are positioned at the same position in the X direction of the visual field of the alignment camera 42, for example, a linear scale read value.

Next, the absolute distance in the Y direction is acquired. In this case, the absolute distance is calculated from rotational position information on the plate cylinder 24 to be output from the rotary encoder in a case where the alignment mark A and the alignment mark C are positioned at the same position in the Y direction of the visual field of the alignment camera 42. Further, alignment adjustment in the Y direction is made not by adjusting the distance but by adjusting the angle.

The distance in the X direction, the angle in the Y direction, and the inclination angle θ obtained in the above-described manners are stored in the storage unit 14. The control unit 18 performs an expansion and contraction treatment in the X direction and the Y direction with respect to the distance in the X direction, the angle in the Y direction, the inclination angle θ, and the ink set pattern data to be printed which is stored in the storage unit 14; and a rotation treatment of the ink set pattern data based on the inclination angle θ and corrects the ink set pattern data. In addition, inclination correction of the printing plate 25 is performed on the corrected ink set pattern data as necessary. In this manner, corrected ink set pattern data is obtained. Further, the timing of jetting the ink from the ink jet head 40 is adjusted by the control unit 18.

Next, the jetting confirmation is performed on the ink jet head 40 (step S14).

In this case, evaluation or jetting observation is performed on a printed material of a test pattern.

The printed material obtained by printing a test pattern is evaluated by observing the printed substrate visually or using a scanner. Further, the evaluation can be performed by only jetting the ink to the printing plate 25 without transferring the ink and observing the ink on the printing plate 25 using the alignment camera 42.

The jetting confirmation area T is provided on the printing plate 25 as described above and the ink is jet to the area. The jetting confirmation area T is provided on the plate cylinder 24 and the ink may be jetted thereto.

The ink on the jetting confirmation area T is removed by a cleaning unit 34 after the evaluation or is transferred to the substrate 31 and then removed.

Further, in a case where the results of the jetting confirmation are out of the predetermined range, a recovery operation is performed by the maintenance unit 36 or the jetting waveform is optimized in the jetting control unit 43.

Along with the jetting confirmation, information on the landing position of the ink jetted to the printing plate 25 is acquired using the alignment camera 42. In the determination processing unit 16, deviation of the landing position is determined, and expansion and contraction or rotation of the ink set pattern data is adjusted again in a case where the landing position is out of the predetermined range in terms of the X direction, the Y direction, and the inclination angle θ.

In Step S14, the jetting confirmation is performed on the treatment liquid of the processing unit 23. The jetting confirmation of the treatment liquid can be performed in the same manner as in the case of the ink. For example, the treatment liquid is jetted to the jetting confirmation area T. The treatment liquid in the jetting confirmation area T is removed by the cleaning unit 34 after the evaluation or removed by being transferred to the substrate 31.

For the treatment liquid, supply of the treatment liquid (Step S30), alignment of the treatment liquid (Step S32), and jetting confirmation of the treatment liquid (Step S34) are performed in parallel with the supply of the ink (Step S10), the alignment of the ink (Step S12), and the jetting confirmation of the ink (Step S14).

The treatment liquid is supplied (Step S30) by sending the treatment liquid (not illustrated) to the sub tank from the treatment liquid tank (not illustrated). Further, the treatment liquid is supplied to the jet head 90 from the sub tank.

Further, the cleaning solution is substituted with the treatment liquid at the time of supplying the treatment liquid. The treatment liquid can be supplied after the cleaning solution is jetted from the jet head 90 using nitrogen gas, but the nitrogen gas is easily mixed. Therefore, it is preferable that the supply of the treatment liquid is carried out by substitution from the cleaning solution.

In a state in which the cleaning solution is supplied to the jet head 90, the jetting confirmation is performed. In a case where the result is not desirable at the time of jetting confirmation, jetting recovery is performed using the maintenance unit 36. In a case where the jetting cannot be recovered, the jet head 90 is replaced as necessary.

At the time of substitution of the cleaning solution with the treatment liquid, for example, the amount of the cleaning solution of the sub tank is reduced to the lower limit. Next, the treatment liquid is added to the sub tank, and the cleaning solution in the jet head 90 is washed away by the treatment liquid. Next, the amount of the treatment liquid in the sub tank is reduced to the lower limit. The cleaning solution is substituted with the treatment liquid by repeatedly performing the process of washing the cleaning solution in the jet head 90 away using the treatment liquid and reducing the amount of the treatment liquid in the sub tank to the lower limit.

In the alignment of the treatment liquid in Step S32, the position of the jet head 90 and the plate position are aligned. First, the alignment marks A to C are read by the alignment camera 42 to detect the positions. After this, since the process is the same as the alignment of the ink in Step S12, the detailed description will not be provided.

In the alignment of the treatment liquid in Step S32, the distance in the X direction, the angle in the Y direction, and the inclination angle θ obtained in the above-described manners are stored in the storage unit 14. The treatment liquid set pattern data is corrected by the control unit 18 performing an expansion and contraction treatment in the X direction and the Y direction with respect to the treatment liquid set pattern data stored in the storage unit 14 using the distance in the X direction, the angle in the Y direction, and the inclination angle θ; and performing a rotation treatment of the treatment liquid set pattern data based on the inclination angle θ. Therefore, corrected treatment liquid set pattern data is obtained. In addition, inclination correction of the printing plate 25 is performed on the corrected treatment liquid set pattern data as necessary. Further, the timing of jetting the treatment liquid from the jet head 90 is adjusted by the control unit 18.

The jetting confirmation of the treatment liquid in Step S34 is carried out by performing evaluation of a printed material of a treatment liquid test pattern or performing jetting observation similar to the jetting confirmation of the ink in Step S14.

The printed material obtained by printing a test pattern is evaluated by observing the printed substrate visually or using a scanner. Further, the evaluation can be performed by only jetting the treatment liquid to the printing plate 25 without transferring the treatment liquid and observing the treatment liquid on the printing plate 25 using the alignment camera 42.

The jetting confirmation area T is provided on the printing plate 25 as described above and the treatment liquid is jet to the area. The jetting confirmation area T is provided on the plate cylinder 24 and the treatment liquid may be jetted to the area. The treatment liquid in the jetting confirmation area T is removed by a cleaning unit 34 after the evaluation or is transferred to the substrate 31 and then removed.

After Steps S10 to S14 and Steps S30 to S34, the treatment liquid is applied to the printing plate 25 (Step S16).

In Step S16, the treatment liquid set pattern data or the corrected treatment liquid set pattern data is sent to the jetting control unit 43, the plate cylinder 24 is allowed to rotate, and the treatment liquid is jetted to the printing plate 25 so as to be applied to the printing plate 25 from the processing unit 23 in the treatment liquid set pattern 94 (see FIG. 14) in the predetermined jetting waveform according to the timing based on the rotational position information on the plate cylinder 24 to be output from the rotary encoder at this time. Step S16 of applying the treatment liquid to the printing plate 25 corresponds to a treatment liquid application step.

As illustrated in FIG. 35, the treatment liquid application step and the inking to the printing plate (Step S18) are performed in parallel with each other during the same rotation of the plate cylinder 24.

In Step S18, the ink set pattern data or the corrected ink set pattern data is sent to the jetting control unit 43, the plate cylinder 24 is allowed to rotate, and the ink is jetted to the printing plate 25 from the ink jet head 40 in the predetermined jetting waveform according to the timing based on the rotational position information on the plate cylinder 24 to be output from the rotary encoder at this time. In this manner, the inking is performed. Step S18 of performing inking to the printing plate corresponds to an ink application step.

The number of times of the application of the treatment liquid (Step S16) and the number of time of the inking (Step S18) are preset, the number of times of the application of the treatment liquid (Step S16) and the number of time of the inking (Step S18) are counted, and then determination of whether the numbers of times respectively reach the set number of times is performed (Step S20). Further, the set number of times is not particularly limited, and the application or the inking may be performed once. In a case where the application or the inking may be performed once, the treatment liquid and the ink are applied to the pattern formation region by performing the application (Step S16) and the inking (Step S18) on the treatment liquid while the plate cylinder 24 is allowed to rotate once. Next, the step proceeds to a drying step (Step S22).

In a case where the set number of times are 2 or greater, the application of the treatment liquid (Step S16) and the inking (Step S18) are repeatedly performed until the number reaches the set number of times, and the step proceeds to the next drying step (Step S22) after the number reaches the set number of times (Step S20). In this case, the application of the treatment liquid (Step S16) and the inking (Step S18) may be performed while the plate cylinder 24 is allowed to rotate once. Further, the application of the treatment liquid (Step S16) is performed while the plate cylinder 24 is allowed to rotate once, and then the inking (Step S18) may be performed while the plate cylinder 24 rotates one more time.

By changing the set number of times, the thickness of a pattern to be formed can be changed. The set number of times is appropriately set according to the thickness of a wiring pattern to be formed.

In the inking (Step S18), the ink is applied to the pattern formation region. In this case, for example, spitting is performed for each rotation of the plate cylinder 24. The spitting is performed in the spit area G of the printing plate 25 or a spit area (not illustrated) provided for spitting on the plate cylinder 24.

As the timing of spitting, the spitting may be performed after a pattern is formed in a printing area or performed for every printing plate. Further, purging, wiping, and spitting are performed by the maintenance unit 36 for every certain number of printing sheets such as every 100 printing plates, and then jetting confirmation may be performed.

Further, in the application of the treatment liquid (Step S16), the treatment liquid is applied to the pattern formation region, and spitting is performed every time the plate cylinder 24 is allowed to rotate once similar to the above-described ink. The spitting is performed in the spit area G of the printing plate 25 or a spit area (not illustrated) provided for spitting on the plate cylinder 24.

Since the timing of spitting of the treatment liquid is the same as the timing of spitting of the above-described ink, the detailed description thereof will not be provided.

Next, the inked printing plate 25 is dried by the drying unit 32 (Step S22) and an ink 52b is dried (see FIG. 7). The step S22 corresponds to the drying step.

Next, the ink 52b (see FIG. 7) of the inked printing plate 25 is transferred to the substrate 31 (Step S24).

First, in the transfer step of Step S24, the substrate 31 is placed on the stage 30 and stands by at the start position Ps. Further, alignment is performed on the substrate 31 for positioning of the pattern of the printing plate 25.

Next, the stage 30 is moved in the transport direction V and the substrate 31 is disposed at the printing position Pp below the plate cylinder 24. Further, the plate cylinder 24 is allowed to rotate so that the printing plate 25 and the surface 31a of the substrate 31 are brought into contact with each other, the ink of the printing plate 25 is transferred to the substrate 31. In addition, after the ink is transferred, the stage 30 is moved in the transport direction V, and the substrate 31 is moved to the end position Pe from the printing position Pp below the plate cylinder 24. Thereafter, the substrate 31 on which a pattern has been formed is moved from the stage 30 and is taken out of the casing 20.

The application of the treatment liquid (Step S16) and the inking (Step S18) are sequentially performed, but the order of these steps is not limited thereto. For example, the inking (Step S18) may be performed earlier than the application of the treatment liquid (Step S16). In both cases, a pattern based on the pattern formation region 27a is obtained, a high-definition printing pattern can be obtained, and the printing accuracy can be improved.

Further, the set number of times of the application of the treatment liquid (Step S16), and the set number of times of the inking (Step S18) may be separately set. The set number of times of the application of the treatment liquid (Step S16), and the set number of times of the inking (Step S18) may be the same as or different from each other.

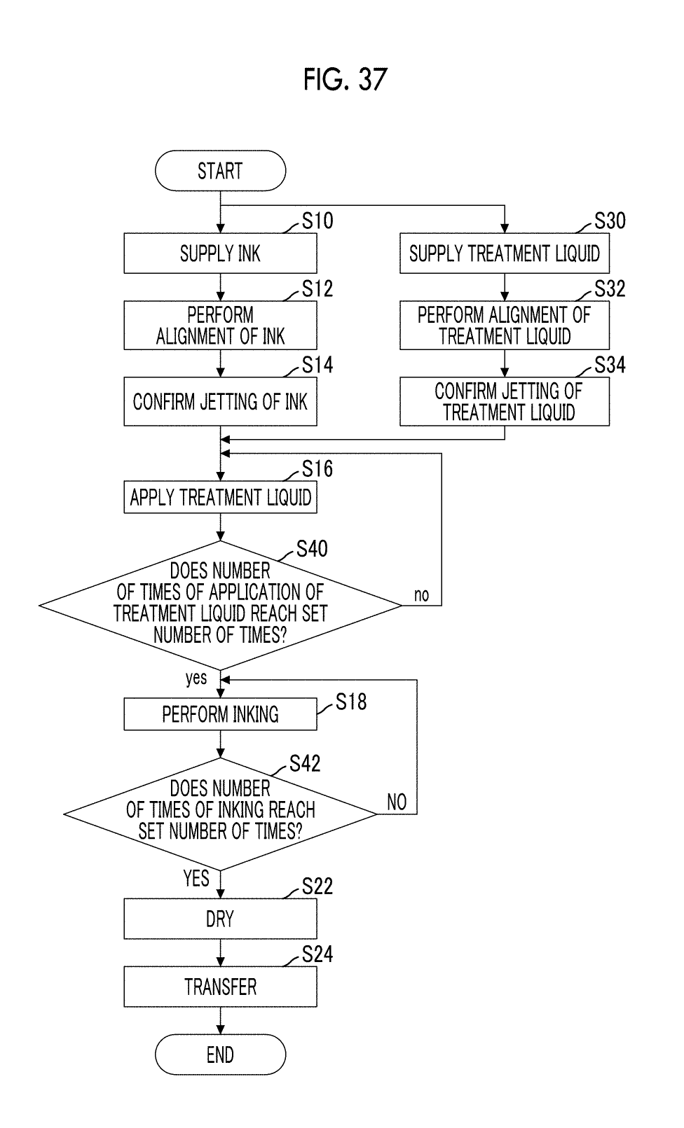

In this case, as illustrated in FIG. 37, the number of times of performing the application of the treatment liquid (Step S16) is counted (Step S40), and the application of the treatment liquid (Step S16) is repeatedly performed until the counted number reaches the set number of times. After the counted number reaches the set number of times, the step proceeds to the inking (Step S18).

In the inking (Step S18), the set number of times is set, the number of times of performing the inking (Step S18) is counted (Step S42), and the inking (Step S18) is repeatedly performed until the counted number reaches the set number of times. After the counted number reaches the set number of times, the step proceeds to the drying step (Step S22).

Even in this case, the application of the treatment liquid (Step S16) and the inking (Step S18) are sequentially performed, but the order of these steps is not limited thereto. For example, the inking (Step S18) may be performed earlier than the application of the treatment liquid (Step S16). In both cases, a pattern based on the pattern formation region 27a is obtained, a high-definition printing pattern can be obtained, and the printing accuracy can be improved.

Hereinafter, constituent units of electronic elements such as a wiring of an electronic circuit and a thin film transistor, or materials of an ink used for forming a precursor of the constituent units of electronic elements such as a wiring of an electronic circuit and a thin film transistor will be described in detail.

As a conductive material, conductive fine particles may be exemplified, and the particle diameter of the conductive fine particles is preferably in a range of 1 nm to 100 nm. In a case where the particle diameter of the conductive fine particles is greater than 100 nm, nozzle clogging is likely to occur and it becomes difficult to jet an ink according to an ink jet method. Further, in a case where the particle diameter of the conductive fine particles is less than 1 nm, the volume ratio of a coating agent to the conductive fine particles is increased, and the proportion of an organic substance in a film to be obtained becomes excessive.

From the viewpoint of aggregating properties of the concentration of the dispersoid, the concentration of the dispersoid is preferably in a range of 1% by mass to 80% by mass.

The surface tension of the dispersion liquid of the conductive fine particles is preferably in a range of 20 mN/m to 70 mN/m. In a case where the surface tension is less than 20 mN/m at the time of jetting a liquid according to an ink jet method, since the wettability of an ink composition with respect to the nozzle surface is increased, a flight curve is likely to occur. In a case where the surface tension is greater than 70 mN/m, since the shape of the meniscus at the nozzle tip is not stabilized, it is difficult to control the jetting amount and the jetting timing.

Examples of the conductive material include fine particles of silver. As metal fine particles other than silver, for example, any one selected from gold, platinum, copper, palladium, rhodium, osmium, ruthenium, iridium, iron, tin, zinc, cobalt, nickel, chromium, titanium, tantalum, tungsten, and indium may be used or an alloy obtained by combining any two or more of these may be used. Further, silver halide may be used, but silver nanoparticles are preferable. Other than the metal fine particles, conductive polymers and fine particles of a superconductor may be used.

Examples of the coating material to be applied to the surface of conductive fine particles include an organic solvent such as xylene or toluene; and citric acid.

A dispersion medium to be used is not particularly limited as long as the conductive fine particles can be dispersed and aggregation is not caused, and examples thereof include water; alcohols such as methanol, ethanol, propanol, and butanol; hydrocarbon-based compounds such as n-heptane, n-octane, decane, tetradecane, toluene, xylene, cymene, durene, indene, dipentene, tetrahydronaphthalene, decahydronaphthalene, and cyclohexylbenzene; ether-based compounds such as ethylene glycol dimethyl ether, ethylene glycol diethyl ether, ethylene glycol methyl ether, diethylene glycol dimethyl ether, diethylene glycol diethyl ether, diethylene glycol methyl ethyl ether, 1,2-dimethoxyethane, bis(2-methoxyethyl)ether, and p-dioxane; and polar compounds such as propylene carbonate, γ-butyrolactone, N-methyl-2-pyrrolidone, dimethylformamide, dimethylsulfoxide, and cyclohexanone. Among these, from the viewpoints of the dispersibility of fine particles and stability of a dispersion liquid, and easily applying an ink jet method, water, alcohols, hydrocarbon-based compounds, and ether-based compounds are preferable. Preferred examples of the dispersion medium include water and hydrocarbon-based compounds. These dispersion mediums may be used alone or in a mixture of two or more kinds thereof.

Further, examples of a binder (additive) include an alkyd resin, a modified alkyd resin, a modified epoxy resin, urethanated oil, a urethane resin, a rosin resin, rosin oil, a maleic acid resin, a maleic anhydride resin, a polybutene resin, a diallyl phthalate resin, a polyester resin, a polyester oligomer, mineral oil, vegetable oil, a urethane oligomer, or a copolymer of (meth)allyl ether and maleic anhydride. The binder may be used alone or in combination of two or more kinds thereof. The copolymers may be added as other monomers, for example, copolymer components such as styrene. Further, a dispersant, a wetting agent, a thickener, a leveling agent, an antifouling agent, a gelling agent, silicon oil, a silicone resin, an antifoaming agent, and a plasticizer may be selected as appropriate and then added to the metal paste of the present invention as an additive.

Further, examples of the solvent include normal paraffin, isoparaffin, naphthene, and alkylbenzenes.

Further, as the conductive material, a conductive organic material can be used, and examples thereof include polymer-based soluble materials such as polyaniline, polythiophene, and polyphenylene vinylene.

In place of fine particles of metals, organometallic compounds may be included. The organometallic compound here indicates a compound in which a metal is precipitated by decomposition resulting from heating. Examples of such organometallic compounds include chlorotriethylphosphine gold, chlorotrimethylphosphine gold, chlorotriphenyl phosphine gold, a silver 2,4-pentanedionato complex, a trimethylphosphine (hexafluoroacetylacetonate)complex, and a copper hexafluoropentanedionatocyclooctanediene complex.

Other examples of the conductive fine particles include metal complexes, for example, a resist, an acrylic resin as a linear insulating material, and a silane compound which becomes silicon at the time of being heated such as trisilane, pentasilane, cyclotrisilane, or 1,1′-biscyclobutasilane. These may be dispersed in a liquid as fine particles or may be present by being dissolved.

Further, as a liquid containing a conductive organic material, an aqueous solution of polyethylenedioxythiophene (PEDOT) and polystyrenesulfonic acid (PPS) which are conductive polymers, doped polyaniline (PANI), or an aqueous solution of a conductive polymer obtained by doping polystyrenesulfonic acid (PSS) on polyethylenedioxythiophene (PEDOT) may be used.

Examples of the material for forming a semiconductor layer include inorganic semiconductors such as CdSe, CdTe, GaAs, InP, Si, Ge, carbon nanotubes, silicon, and ZnO; and organic semiconductors, for example, organic low molecules such as pentacene, anthracene, tetracene, and phthalocyanine, polyacetylene-based conductive polymers, polyphenylene-based conductive polymers such as polyparaphenylene and derivatives thereof, and polyphenylene vinylene and derivatives thereof, heterocyclic conductive polymers such as polypyrrole and derivatives thereof, polythiophene and derivatives thereof, and polyfuran and derivatives thereof, and ionic conductive polymers such as polyaniline and derivatives thereof.

Further, as a material constituting an interlayer insulating film with excellent electrical insulating properties, in other words, an insulating material, the following materials can be used. Specific examples of the organic material include polyimide, polyamide imide, an epoxy resin, silsesquioxane, polyvinyl phenol, polycarbonate, a fluorine-based resin, polyparaxylylene, and polyvinyl butyral. The polyvinyl phenol and polyvinyl alcohol may be cross-linked using an appropriate crosslinking agent. Other examples of the organic material include fluorinated polymers such as polyfluorinated xylene, fluorinated polyimide, fluorinated polyallyl ether, polytetrafluoroethylene, polychlorotrifluoroethylene, poly(α,α,α′, α′-tetrafluoro-paraxylene), poly(ethylene/tetrafluoroethylene), poly(ethylene/chlorotrifluoroethylene), and a fluorinated ethylene-propylene copolymer; polyolefin-based polymers; and polystyrene, poly(α-methylstyrene), poly(α-vinylnaphthalene), polyvinyltoluene, polybutadiene, polyisoprene, poly(4-methyl-1-pentene), poly(2-methyl-1,3-butadiene), polyparaxylene, poly[1,1-(2-methylpropane)bis(4-phenyl)carbonate], polycyclohexyl methacrylate, polychlorostyrene, poly(2,6-dimethyl-1,4-phenyleneether), polyvinyl cyclohexane, polyallylene ether, polyphenylene, polystyrene-co-α-methylstyrene, an ethylene-ethyl acrylate copolymer, poly(styrene/butadiene), and poly(styrene/2,4-dimethylstyrene).

Examples of the porous insulating film include porous insulating films such as phosphosilicate glass obtained by adding phosphorus to silicon dioxide, boron phosphosilicate glass obtained by adding phosphorus and boron to silicon dioxide, polyimide, and polyacryl. Further, a porous insulating film having a siloxane bond such as porous methyl silsesquioxane, porous hydrosilsesquioxane, or porous methylhydrosilsesquioxane can be formed.

In a case where the above-described materials are used, a solvent or a dispersion medium can be used as a treatment liquid.

Further, the material contained in the ink is not limited to those described above, and optimal materials are selected depending on the purpose thereof. For example, an ink containing a colorant used for producing a color filter can be applied. As the colorant, known dyes and pigments are exemplified. Further, such an ink may contain the above-described dispersion mediums and binders.

Even in this case, the dispersion medium contained in the ink can be used as a treatment liquid.

The basic configuration of the present invention is as described above. Hereinbefore, the printing method of the present invention has been described in detail, but the present invention is not limited to the above-described embodiments, and various improvements and modifications can be made within the range not departing from the scope of the present invention.

### EXPLANATION OF REFERENCES

10: printing device
12: printing device main body
14: storage unit
16: determination processing unit
18: control unit
20: casing
20a: interior
22: image recording unit
23: processing unit
24: plate cylinder
24a: surface
24b: rotating shaft
25: printing plate
25a: plate surface
25b: depression
27a: pattern formation region
27b: non-pattern formation region
29: planographic plate
29a: surface
29b: relief printing plate
30: stage
31: substrate
31a: surface
32: drying unit
33: ionizer
34: cleaning unit
35: removal unit
36: maintenance unit
39: transfer unit
40: ink jet head
40a: head module
41: nozzle
42: alignment camera
43: jetting control unit
45: ink droplet
46: carriage
47: ink
48: linear motor
49: revolving unit
52b: ink
80: thin film transistor, TFT
82: gate electrode
84: channel region
86a: source electrode
86b: drain electrode
90: jet head
92: treatment liquid droplet
94: set pattern
96, 96a: ink set pattern
100: wiring pattern
110: change in time of relative position between plate cylinder and processing unit
111: period for application of treatment liquid
111a, 113a: start position
111b, 113b: end position
112: change in time of relative position between plate cylinder and image recording unit
113: period for application of ink
A, B, C, D: alignment mark
G: spit area
G₁₁, G₁₂, G₂₁, G₂₂, G₃₁, G₃₂: printing area
H1: first direction
H2: second direction
M₁, M₂, M₃: positioning area
P_{c1}, Pᵢ₁: start position
P_{c2}, Pᵢ₂: end position
Pe: end position
Pp: printing position
Ps: start position
S10, S12, S14, S16, S18, S20, S22, S24, S26, S28, S30, S32, S34, S40, S42: step
T: jetting confirmation area
V: transport direction
α: angle
θ: inclination angle

What is claimed is:

1. A printing method comprising:
a treatment liquid application step of applying a treatment liquid, in a treatment liquid set pattern, to a pattern formation region of a printing plate in the printing plate on which a pattern has been formed;
an ink application step of applying an ink, in an ink set pattern, to the pattern formation region of the printing plate to which the treatment liquid has been applied; and
a transfer step of transferring the ink applied to the pattern formation region of the printing plate to a substrate,
wherein the treatment liquid is used for increasing a second diameter of the ink after application of the treatment liquid compared to a first diameter of the ink landed on the pattern formation region without application of the treatment liquid.

2. The printing method according to claim 1,
wherein the ink application step is repeatedly performed a plurality of times after the treatment liquid application step has been repeatedly performed a plurality of times, and then the transfer step is performed.

3. The printing method according to claim 1,
wherein the transfer step is performed after the treatment liquid application step and the ink application step have been repeatedly performed a plurality of times.

4. A printing method comprising:
an ink application step of applying an ink, in an ink set pattern, to a pattern formation region of a printing plate in the printing plate on which a pattern has been formed;
a treatment liquid application step of applying a treatment liquid, in a treatment liquid set pattern, to the pattern formation region of the printing plate to which the ink has been applied; and
a transfer step of transferring the ink applied to the pattern formation region of the printing plate to a substrate,
wherein the treatment liquid is used for increasing a second diameter of the ink after application of the treatment liquid compared to a first diameter of the ink landed on the pattern formation region without application of the treatment liquid.

5. The printing method according to claim 4,
wherein the treatment liquid application step is repeatedly performed a plurality of times after the ink application step has been repeatedly performed a plurality of times, and then the transfer step is performed.

6. The printing method according to claim 4,
wherein the transfer step is performed after the ink application step and the treatment liquid application step have been repeatedly performed a plurality of times.

7. The printing method according to claim 1,
wherein the treatment liquid is applied according to an ink jet method.

8. The printing method according to claim 2,
wherein the treatment liquid is applied according to an ink jet method.

9. The printing method according to claim 3,
wherein the treatment liquid is applied according to an ink jet method.

10. The printing method according to claim 1,
wherein the ink is applied according to an ink jet method.

11. The printing method according to claim 2,
wherein the ink is applied according to an ink jet method.

12. The printing method according to claim 3,
wherein the ink is applied according to an ink jet method.

13. The printing method according to claim 1,
wherein at least a part of the treatment liquid set pattern overlaps with at least a part of the ink set pattern.

14. The printing method according to claim 2,
wherein at least a part of the treatment liquid set pattern overlaps with at least a part of the ink set pattern.

15. The printing method according to claim 3,
wherein at least a part of the treatment liquid set pattern overlaps with at least a part of the ink set pattern.

16. The printing method according to claim 1, which is used for producing an electronic device.

17. The printing method according to claim 2, which is used for producing an electronic device.

18. The printing method according to claim 3, which is used for producing an electronic device.

19. The printing method according to claim 16, which is used for forming a wiring pattern or an electrode.

20. The printing method according to claim 17, which is used for forming a wiring pattern or an electrode.
